(19) United States
(12) Patent Application Publication
(10) Pub. No.: US 2011/0306187 A1
(43) Pub. Date: Dec. 15, 2011

(54) METHOD AND APPARATUS FOR SILICON REFINEMENT

(76) Inventors: Peter Dold, Halle/Saale (DE); Athanasios Tom Balkos, Waterloo (CA); Jeffrey Dawkins, Kitchener (CA)

(21) Appl. No.: 13/160,769

(22) Filed: Jun. 15, 2011

Related U.S. Application Data
(63) Continuation of application No. PCT/CA2009/001877, filed on Dec. 23, 2009.
Application No. PCT/CA2009/001877 is a continuation-in-part of application No. PCT/US2008/013997, filed on Dec. 23, 2008.

(51) Int. Cl. H01L 21/20; C23C 16/448; C09D 1/00; C23C 16/24

(52) U.S. Cl. 438/478; 118/726; 420/591; 257/E21.09

(57) ABSTRACT

A method and respect material for the production of chlorosilanes (primarily: trichlorosilane) and the deposition of high purity poly-silicon from these chlorosilanes. The source for the chlorosilane production consists of eutectic or hypo-eutectic copper-silicon, the concentration range of said copper-silicon is between 10 and 16 wt % silicon. The eutectic or hypo-eutectic copper-silicon is cast in a shape suitable for a chlorination reactor, where it is exposed to a process gas, which consists, at least partially, of HCl. The gas reacts at the surface of the eutectic or hypo-eutectic copper-silicon and extracts silicon in the form of volatile chlorosilane. The depleted eutectic or hypo-eutectic material might be afterwards recycled in such a way that the amount of extracted silicon is replenished and the material is re-cast into the material shape desired.

(This application is a Continuation of PCT/CA2009/001877, Filed Dec. 23, 2009 and is a Continuation-In-Part of PCT Application No. PCT/US2008/013997, Filed Dec. 23, 2008 both of which are herein incorporated by reference.)

### FIELD OF THE INVENTION

The invention relates to a method and an apparatus for silicon refinement. In particular, the invention relates to a method and an apparatus for the generation of chlorosilane and the deposition of high purity silicon.

### BACKGROUND OF THE INVENTION

Metallurgical grade silicon needs refinement before it can be used for photovoltaic or semiconductor applications. Conventionally, this process is performed in several steps carried out in a serial manner: In the first step, chlorosilanes or monosilanes are produced, e.g. TCS—trichlorosilane SiHCl3, STC—silicon tetrachloride SiCl4, dichlorosilane SiH2Cl2, or monosilane SiH4, generally by a kind of fluidized bed reactor, for example as described in U.S. patent application publication no. 2007/0086936A1. In the following step, the product gas is captured and purified by fractional distillation in order to remove gaseous metal chlorides, BCl3, PCl3, CH4 etc. The high purity chlorosilanes are than used as process gases for the so called Siemens process, in which the silanes react back to silicon and various gas species. The Siemens process is an open loop system, the process has to be fed continuously with process gases, and the exhaust gases have to be continuously captured and treated by special procedures. This makes the Siemens process rather expensive with respect to the required gas infrastructure, the logistics, and the effort for waste gas treatment. Examples of the Siemens process are provided in U.S. Pat. Nos. 2,999,735; 3,011,877; and 6,221,155, as well as in a variety of textbooks (e.g. A. Luque and S. Hegedus (Eds.): “Handbook of Photovoltaic Science and Engineering”, Wiley & Sons Ltd, ISBN 0-471-49196-9).

Other known approaches use chemical treatments, such as etching and leaching, of metallurgical silicon, in combination with single or multiple solidification cycles to remove metallic impurities and to reduce the concentration of electrically active elements, such as phosphor and boron. The final product, the so called upgraded metallurgical silicon (umg-Si) is suitable for photovoltaic applications, but still contains rather higher concentrations of impurities.

Casting of silicon with other metals is a known technique for pre-conditioning of mg-Si, for example in U.S. Pat. No. 4,312,848, in which case aluminum is used as a solvent for silicon.

The use of silicon concentration>20% wt for copper-silicon as source material for the production of chlorosilanes is described in U.S. Pat. No. 4,481,232 by Olson. The material, in Olson, was placed in a single chamber compartment. Copper is known to act not only as a catalyst for improving the productivity of chlorosilane generation but, in addition, in acting as a getter material for metallic impurities. In Olson's patent, the copper-silicide is placed in the direct vicinity of a heated graphite filament. Movement of the gas is provided by natural convection caused by the temperature difference between the hot filament and the relative cold walls of the chamber. Generally single chamber arrangements can cause several problems. For example, in the method described in U.S. Pat. No. 4,481,232 only a limited amount of copper-silicide can be charged into the chamber, the alloy is heated indirectly by the filament due to its proximity to the filament. The alloy temperature cannot therefore be suitably controlled and will increase beyond the optimal temperature range for gaseous silicon production. One skilled in the art will recognize that a too high temperature will mobilize the metallic impurities captured in the copper-silicon alloy or the copper itself, which will result in an elevated level of metallic impurities in the refined silicon. It will be further recognized that, especially in the presence of hydrogen, too high temperatures will shift the chemical equilibrium in direction to solid silicon instead of gaseous chlorosilanes, thus lowering the productivity. The single chamber set-up also has a lack of adequate suppression of volatile impurities and particles which will affect the purity of the deposited silicon. It is well known in silicon industry that even trace amounts of copper can be highly unfavourable for the use of silicon in semiconductor or solar applications.

The single chamber arrangement described in U.S. Pat. No. 4,481,232 is therefore only suitable for laboratory size applications and would not be optimal for scale up. A significant disadvantage of the high concentration (e.g. 20-30% wt silicon) copper-silicon alloy proposed by Olson is that the alloy has a tendency to oxidize when exposed to atmosphere and it is swelling and disintegrating during the chlorination process. The latter can be caused by the substantive silicon crystallites and associated cracking interspersed in the eutectic copper-silicon alloy.

High purity silicon is required for any application in electronic industry, such as the use of solar cells or manufacturing of semiconducting devices. The necessary purity levels for any electronic application are significantly higher than what is provided by so-called metallurgical grade silicon (m.g.-silicon). Therefore, complicated and expensive refinement steps are required. This results in a strong need for more cost-efficient and energy efficient processes, in order to purify m.g.-silicon in a simplified way.

In general, two approaches for the refinement of silicon are distinguished, the chemical path and the metallurgical path. In case of the chemical refinement, the m.g.-silicon is transferred into the gas phase in form of a chlorosilane and is later on deposited in form of a Chemical Vapor Deposition (CVD) process (use of trichlorosilane, e.g. conventional Siemens process, see e.g. U.S. Pat. Nos. 2,999,735; 3,011,877; 3,979,490; and 6,221,155, or use of silane, see e.g. U.S. Pat. Nos. 4,444,811 or 4,676,967). In this case, the first step is the formation of chlorosilanes from small size (grained/crashed) silicon particles in a Fluidized Bed Reactor, and the consequent distillation of the gaseous species. Since the silicon is used in form of small particles, which are fully exposed to the process gas, impurities (metallic impurities, boron, phosphorous etc.) can also go into the gas phase and therefore have to be removed by distillation before the chlorosilanes can be used for silicon deposition, or for further chemical treatment like hydrogenization for the production of silane.

The metallurgical approach involves the casting of m.g.-silicon, either just as silicon (and removal of impurities by segregation and oxidation, as disclosed e.g. in WO/2008/031,229 A1) or as an alloy of m.g.-silicon with a metal (e.g. aluminum). In the latter case, the metal acts as a catcher/getter for impurities, but it has to be leached out wet-chemically, before the refined silicon is cast into ingots. The metallurgical approach can also result in significantly lower purity levels than the chemical path.

A major disadvantage of the chemical path is the fact, that during the chlorosilane formation, small size particles of the m.g. silicon stock are required in order to provide a large silicon surface for reaction. Further, undesirable high pressures and/or high temperatures are required to keep the reaction between m.g.-silicon and the process gas (HCl, or HCl, H2 mixture) going. This can result in high impurity concentrations in the chlorosilane stream (metal-chlorides, BCl3, PCl3, CH4 etc.), which can require intensive purification by distillation.

Metals such as copper are known to act as a catalyst for the reaction between silicon and HCl, as it lowers the required temperatures and increases the yield (e.g. US patent 2009/0060818 A1). For the use as a catalyst, copper—or more likely copper in form of copper-chloride—is brought into contact with m.g. silicon particles and thus improves their reactivity with the HCl. Since, for this application, the metal such as copper is used only as a catalyst for the separate m.g. silicon stock, the applied concentrations of the metal/copper catalyst are in the lower per centum or per mill range. In this range case, metal such as copper has no function with respect to purification or gettering (i.e. filtering) of impurities from the m.g. silicon stock.

The use of a copper-silicon alloy for the purification of m.g.-silicon was proposed by Jerry Olson (U.S. Pat. No. 4,481,232; see also R. C. Powell, J. M. Olson, J. of Crystal Growth 70 (1984) 218; P. Tejedor, J. M. Olson, J. of Crystal Growth 94 (1989) 579; P. Tejedor, J. M. Olson, J. of Crystal Growth 89 (1988) 220). Olson cast copper-silicon pieces of greater than 20% wt Si (for example 20-30% wt Si), which he placed in direct vicinity to a heated silicon filament. The inserted process gases (HCl—H2 mix) extracted silicon from the alloy in the form of a chlorosilane and Olson was able to deposit purified silicon on the silicon filament. Extraction of the silicon took place in a temperature range between 400 and 750 C. It should be recognized that in the case of using metal silicon alloys, significant operational disadvantages can be encountered including instability of the alloy material both inside and outside of the purification process in the presence of crystallites in the allow material 16 (e.g. the case for two phases present in the alloy material).

### SUMMARY OF THE INVENTION

It is an object of the present invention to provide systems, processes and/or materials for the production of vapour deposition transport gas from a low purity silicon source, the purification of said low purity silicon, and/or the consequent production of higher purity silicon to obviate and/or mitigate at least one of the above-presented disadvantages.

The present invention provides a method for producing high purity silicon using an apparatus comprising a first chamber (chlorination chamber) configured to receive a silicon-metal alloy and a gas source operable to transport silicon, and a second chamber (deposition chamber), fluidly connected to the first chamber, comprising at least one filament configured to receive silicon thereon by deposition, wherein upon deposition of silicon, a secondary gas mixture is formed. A first gas flow path is configured to allow passage of the gas transporting silicon from the chlorination chamber to the deposition chamber and a second gas flow path is configured to allow passage of the secondary gas mixture from the deposition chamber to the chlorination chamber. The secondary gas mixture is capable to act as the gas source for the chlorination of the silicon when received in the chlorination chamber.

In another aspect the present invention provides a method for producing high purity silicon using an apparatus having fluidly connected chlorination and deposition chambers, comprising the steps of (i) providing an silicon-metal alloy adapted to provide a source of silicon in the chlorination chamber, (ii) providing an initial primary gas mixture comprising hydrogen and a source of chlorine, (iii) actively heating the silicon-metal alloy in the chlorination chamber to a temperature at which the silicon-metal alloy and the primary gas mixture react and form a silicon source gas comprising at least one of one or more chlorosilanes, (iv) providing, in the deposition chamber, at least one filament configured to receive silicon thereon, (v) heating the at least one filament to a temperature to cause the silicon source gas to deposit silicon on the surface of the at least one filament and produce a secondary gas mixture comprising a source of chlorine, (vi) allowing the secondary gas mixture to flow back to the chlorination chamber to act as the gas mixture with which the silicon-metal alloy reacts and (vii) repeating steps iii) and vi) until sufficient silicon has been deposited.

In a further embodiment, the present invention provides a method for producing high purity silicon using an apparatus having fluidly connected chlorination and deposition chambers, comprising the steps of (i) providing a silicon-metal alloy adapted to provide a source of silicon in the chlorination chamber, (ii) providing an initial gas source consisting of a mixture of H2, HCl and chlorosilanes, operable to provide a chemical vapour transport gas for transporting silicon, (iii) actively heating the silicon-metal alloy in the chlorination chamber to a temperature sufficient to allow the initial gas source to react with the alloy to produce a process gas comprising a gaseous silicon source, (iv) providing at least one filament configured to receive silicon thereon, in the deposition chamber, (v) heating the at least one filament to a temperature to cause the gaseous silicon to deposit on the surface of the at least one filament and produce a secondary process gas source operable to provide a chemical vapour transport gas for transporting silicon, (vi) allowing the secondary process gas source to flow back to the chlorination chamber to act as the gas source to react with the silicon-metal alloy and (vii) repeating steps iii) and vi) until sufficient silicon has been deposited on the at least one filament.

Complicated and expensive refinement steps can be required in today's high purity silicon purification processes. Other disadvantages for today's processes are high impurity concentrations in the chemical vapour, which can require intensive purification by distillation. Hyper-eutectic alloys have been in prior art processes, however significant operational disadvantages exist including instability of the alloy material both inside and outside of the purification process. Contrary to present purification systems and methods there is provided a method for purifying silicon comprising: reacting an input gas with a metal silicon alloy material having a silicon percent weight at or below the eutectic weight percent of silicon defined for the respective metal silicon alloy; generating a chemical vapour transport gas including silicon obtained from the atomic matrix of the metal silicon alloy material; directing the vapour transport gas to a filament configured to facilitate silicon deposition; and depositing the silicon from the chemical vapour transport gas onto the filament in purified form.

A further aspect provided is a method for purifying silicon comprising: reacting an input gas with a metal silicon alloy material having a silicon percent weight at or below the eutectic weight percent of silicon defined for the respective metal silicon alloy; generating a chemical vapour transport gas including silicon obtained from the atomic matrix of the metal silicon alloy material; directing the vapour transport gas to a filament configured to facilitate silicon deposition; and depositing the silicon from the chemical vapour transport gas onto the filament in purified form.

A further aspect is a metal silicon alloy material having a silicon percent weight at a selected eutectic weight percent of silicon defined for the respective metal silicon alloy for use in a chemical vapour deposition (CVP) process, such that the presence of silicon crystallites in the alloy material is at or below a defined maximum crystallite threshold.

A further aspect is a metal silicon alloy material having a silicon percent weight at or below the eutectic weight percent of silicon defined for the respective metal silicon alloy for use in a chemical vapour deposition (CVP) process.

A further aspect is an apparatus for purifying silicon comprising: a first reactor for reacting an input gas with a metal silicon alloy material having a silicon percent weight at or below the eutectic weight percent of silicon defined for the respective metal silicon alloy and for generating a chemical vapour transport gas including silicon obtained from the atomic matrix of the metal silicon alloy material; an output for directing the vapour transport gas to a filament configured to facilitate silicon deposition; and a second reactor for depositing the silicon from the chemical vapour transport gas onto the filament in purified form.

A further aspect is a metal silicon alloy material having a silicon percent weight at a selected eutectic weight percent of silicon defined for the respective metal silicon alloy for use in a chemical vapour deposition (CVP) process, such that the presence of silicon crystallites in the alloy material is at or below a defined maximum crystallite threshold.

A further aspect is a metal silicon alloy material having a silicon percent weight at or below the eutectic weight percent of silicon defined for the respective metal silicon alloy for use in a chemical vapour deposition (CVP) process.

It is an object to use a copper-silicon compound in order to make use of the catalytic nature of copper and to use a metal-silicon matrix to hold back/getter impurities.

It is another object to refine low-purity grade m.g.-silicon in such a way that high purity silicon for use as e.g. feed-stock for photovoltaic applications is produced.

Further example objects are: produce a copper-silicon source for use in a chlorination reactor, which (1) inhibits the formation of micro-cracks during casting, (2) has a desired shelf-time and inhibits significant oxidation, (3) inhibits swelling/expansion during the use in a chlorination reactor, (4) inhibits release of dust or powder during the use in chlorination reactors, (5) results in the production of high purity silicon above a selected resistivity threshold, and/or (6) can be handled and can be re-melted/cast (i.e. recycled) once significantly depleted of silicon.

### BRIEF DESCRIPTION OF THE DRAWINGS

The present invention will now be described in further detail with reference to the following figures:

FIG. 1 is a schematic sectional view showing an apparatus according to the present invention for the generation of chlorosilanes and the deposition of high purity silicon in a closed loop arrangement, the two chambers are fully separated and are connected by a piping system;

FIG. 2 is a schematic sectional view showing an apparatus according to the present invention for the generation of chlorosilanes and the deposition of high purity silicon in a closed loop arrangement where the two chambers are attached but separated by an intermediate plate;

FIG. 3 is a block diagram showing a general purification process and apparatus using alloy material as an example of the apparatus and methods of FIG. 1;

FIG. 4 is an example phase diagram for the alloy material of FIG. 3;

FIG. 5 is an example matrix of the alloy material of FIG. 3;

FIG. 6 shows an alternative embodiment of eutectic properties of a metal alloy material for the apparatus of FIG. 3;

FIG. 7a shows undesirable hyper-eutectic properties of the alloy material for the apparatus of FIG. 3;

FIG. 7b shows an example result of the alloy material of FIG. 8a after use in the apparatus of FIG. 3;

FIG. 8 shows oxidation behaviour of eutectic copper-silicon alloy material versus oxidation behaviour of hyper-eutectic alloy of FIG. 7a;

FIG. 9a is a further embodiment of the alloy material of FIG. 5;

FIG. 9b shows a representation of the silicon content after being depleted in the vapour generation process of the apparatus of FIG. 3;

FIG. 10 is a block diagram for an example method of a chemical vapour production and deposition process of FIG. 3;

FIG. 11 is a block diagram of an example chemical vapour production process of FIG. 3;

FIG. 12 is an example casting apparatus for the alloy material of FIG. 3;

FIG. 13 is a block diagram for an example casting process using the apparatus of FIG. 12;

FIG. 14a is a diagram of resistivity measured though a thickness of deposited silicon obtained from eutectic or hypo eutectic alloy material used in the apparatus of FIG. 3; and

FIG. 14b is a diagram of resistivity measured though a thickness of deposited silicon obtained from eutectic or hypo eutectic alloy material used in the apparatus of FIG. 3.

### DETAILED DESCRIPTION OF THE PREFERRED EMBODIMENTS

It is recognised that a significant disadvantage of the copper-silicon alloy proposed by Olson is that the alloy appears to be hyper-eutectic and Applicant has confirmed that hyper-eutectic shows a tendency to oxidize when exposed to atmosphere and it swells and disintegrating during the chlorination process. The latter can be caused by the presence of substantive silicon crystallites and associated cracking interspersed with the eutectic copper-silicon matrix in the alloy material.

In the description that follows, a number of terms are used extensively, the following definitions are provided to facilitate understanding of various aspects of the invention. Use of examples in the specification, including examples of terms, is for illustrative purposes only and is not intended to limit the scope and meaning of the embodiments of the invention herein. Numeric ranges are inclusive of the numbers defining the range. In the specification, the word “comprising” is used as an open-ended term, substantially equivalent to the phrase “including, but not limited to,” and the word “comprises” has a corresponding meaning. Further, it is recognized that specific measures, as provided by illustrative example, can be approximate for purposes of controlling the pressure, temperature, and/or silicon percentage content in the alloy material 16. It is recognized that minor variance in the stated specific measures is accommodated for if the impact of such variance is insubstantial to processes 9,11 and/or the crystallite 120 content of the alloy material 16. For example, approximate temperatures can mean variation in the temperature by plus or minus a degree. For example, approximate silicon percent weights can mean plus or minus of the specific percent weight measure in the range of 0.01-0.2.

The present invention allows for the refinement of silicon, the production of chlorosilanes, and the deposition of high purity silicon in a re-circulating, closed loop system. At the beginning of the process the chambers are filled with a mixture of H2 and HCl. The ratio of the two gases is in the range of 1:9 to 9:1 and preferably in the range of 1:2 and 2:1. The process gases are then circulated between the chambers, chlorosilanes are formed in the one chamber, in which the low purity silicon is placed in the form of a silicon-metal alloy, referred to herein as a chlorination chamber, and silicon is deposited in the other one, where heated silicon filament(s) are located, referred to herein as a deposition chamber. When the rods are harvested and the chlorination chamber is re-charged with silicon-metal alloy, the gas which has a volume equivalent to the volume of the apparatus is then removed and treated. It may either be collected and stored in a separate tank for direct reuse, or it may be further processed as waste gas and neutralized. The use of the term chlorosilanes refers to any silane species having one or more chlorine atoms bonded to silicon. The produced chlorosilanes may include, but are not limited to, dichlorosilanes (DCS), trichlorosilanes (TCS) and silicontetrachloride (STC). Preferentially, TCS is used for the deposition of purified silicon.

The present invention provides an apparatus and method that facilitates the removal of metal impurities from the deposition process. In particular, the present invention provides a deposition method that uses a silicon-metal alloy and that provides high purity silicon with the removal of metallic impurities. Some metallic impurities do not form volatile chlorides, like e.g. Fe, Ca, Na, Ni, or Cr and thus stay with the alloy in the chlorination chamber. Others, which form chlorides with a rather low boiling point (e.g. Al or Ti), will evaporate, but do more preferably condensate on cold surfaces than being deposited on the hot silicon filament in the deposition chamber.

As stated above, the chamber in which the refining process is performed is also referred to herein as a chlorination chamber. The chlorination chamber is described in Applicant's co-pending application titled Apparatus for the Production of Chlorosilanes. The chamber in which the deposition occurs is also referred to herein as a deposition chamber.

In a further aspect the present invention provides a method for the deposition of high purity silicon having a chlorination chamber configured to continuously produce a process gas source of chlorosilanes and a deposition chamber configured to receive the process gas source for subsequent deposition of silicon.

In a further aspect of the invention, two or more chlorination chambers are connected to one deposition chamber.

In a further aspect of the invention, two or more deposition chambers are connected to one chlorination chamber.

The chlorination and the deposition chambers may be attached, but separated by diverters or plates, or they may be detached and connected by a piping system.

In one embodiment the chlorination and deposition chambers of the apparatus are operable to receive an initial source of H2 and HC1 and once received the apparatus is configured to continuously generate a chlorosilane gas mixture without any further addition of an external gas mixture beyond the initial gas source.

In another embodiment the chlorination chamber is configured to receive a gaseous source of chlorine from within the closed loop apparatus (i.e. the exhaust gases from the deposition process—mixture of mainly H2, HCl, TCS and STC) and is operable to use this gas mixture to bring more silicon into the gas phase in the form of chlorosilane. The present invention provides the capability to re-convert any excess STC, which is generated during the deposition of silicon, back into TCS.

To form the silicon-metal alloy used in the apparatus and method of the present invention, any metal might be used, provided that the metal has a low vapour pressure and shows a limited reaction with HCl gas and hydrogen, the metal should not form a gaseous species which tends to decompose on the hot filaments in the deposition chamber. Preferably the metal used does not form a volatile metal-chloride in the range of the working temperature of the chlorination chamber. Potential alloy forming metals include, but are not limited to, copper, nickel, iron, silver, platinum, palladium, chromium or combinations of these metals. In a preferred embodiment of the present invention the alloy is a silicon-copper alloy.

The silicon-metal alloy should contain at least 10% silicon to provide a high productivity, but lower silicon concentrations work as well although with a lower productivity. In order to provide a high productivity and in order to improve the selectivity, at least one component of the silicon-metal alloy should catalyze the hydro-chlorination of silicon.

In a preferred embodiment, the material used for the chlorination process is formed by eutectic or hypo-eutectic copper-silicon. Eutectic and hypo-eutectic copper-silicon is distinguished by a low affinity to oxidation when exposed to atmosphere. Further, swelling or powdering during the chlorination process is reduced. This reduces the risk of particle contamination in the gas stream. Further, it enhances the gettering of impurities, since the process gas may not penetrate into the bulk of the material, as it is the case for hyper-eutectic copper-silicon alloys due to the serious swelling of hyper-eutectic material. Therefore, reaction with the process gas can take place on the surface of the bricks and fast diffusing elements will reach the surface. Silicon is known to have an extraordinary/preferred high diffusion coefficient in copper-silicon (over that of impurities in the alloy), which can provide an excellent filter/getter effect for impurities.

The alloy to be used may take any form, for example bricks, plates, granules, chunks, pebbles or any other shape, which allows an easy charging of the chamber and which preferably provides a large surface to volume ratio. The alloy might be produced by a casting process or it might be sintered.

The present invention relates to the production of high purity, cost efficient silicon. Further, this invention relates to the refining of raw silicon, for example, but not limited to, metallurgical grade silicon of approx. 98 to 99.5% purity, into high purity silicon having a purity with respect to metallic impurities better than 6N. The invention further provides a process and an apparatus for the refining and production of solar grade silicon which can be used, for example, as base material for forming multi-crystalline or single crystalline ingots for wafer manufacturing.

The present invention further provides an apparatus and method that allows for direct control of the temperature of the silicon source, i.e. alloy, separate from the control of the filament upon which the silicon is to be deposited.

The chlorination chamber, of the present invention, is sized and shaped to contain the alloy and to receive the initial process gases described herein. There are no size limitations for the chlorination chamber besides structural and mechanical considerations. It will be understood that the chlorination chamber should be connected to, or contain, a heating system configured to heat the chlorination chamber as described herein. The chamber may be cylindrical or box-shaped or shaped in any geometry compatible with the described process. In one embodiment the chamber is cylindrical which provides for easier evacuation and better over-pressure properties. The chamber is configured to be heated either with an internal heater or with an external heater connected to the chamber, described below in further detail.

The chamber may be manufactured from any material operable to withstand the corrosive atmosphere and the range of operational temperature. To hold the silicon-alloy in place a charge carrier may be used, the charge carrier has to withstand the same atmosphere and temperature as the chamber and therefore may be made from similar material, providing it is not forming an alloy within the temperature used for the process.

The chamber includes an inlet and an outlet port for the process gases. Preferably, the inlet and outlet ports are designed in such a way that a uniform flow of the process gases is provided for the alloy enclosed in the chamber. Flow guiding systems may be used to improve the uniformity. The outlet port may be equipped with a mesh or a particle filter, depending on the application to which the gases leaving the chamber are to be used.

The chamber may also include an agitator to provide additional circulation in the chamber and to assist in the transportation of the process gases. In one embodiment the chamber may include an agitator that is an internal propeller. The propeller might be implemented anywhere within the chamber as long as a uniform movement of the gas is provided. Alternatively, the chamber may be connected to an external pump, for example a pump or blower, that assists in the transportation of the process gases in the chamber. It will be understood that the pump or blower is exposed to corrosive gases and therefore should be made of material that can withstand such conditions. The external pump may be positioned near the inlet or the outlet ports.

The silicon-metal alloy placed in the chamber is heated to an appropriate temperature to a fast reaction of the process gases with the silicon and to guarantee a high output. As described above, the chamber may contain a heating device or may be connected to an external heating device. The heating device is used to heat the chamber and the alloy directly, i.e. it is the primary source of heat. The term ‘active heating’, or variations thereto, is used to describe a way of heating the alloy that is controlled, in which the temperature of the alloy is changed by changing the output of the heating device. The temperature of the exhaust gases from the deposition chamber entering the chlorination chamber provide an additional source of heat, as well as the exothermic reaction of the chlorosilane formation, but this is of secondary order. Control of the alloy temperature is directly related to the heating device.

In the case of an internal heating device, a graphite heater might be used, preferably a SiC-coated one, or any other material suitable for use in a corrosive atmosphere. An internal heating device provides enhanced heating for a large diameter reactor and also allows operation of the chamber with lower wall temperatures which improves the corrosion resistance of the vessel material. If an external heating device is used any type of resistance heater may be used and connected to the chamber. The external heating device can be placed near the external wall of the chamber, it can be connected directly to it, or can even be part of the chamber wall. It will be understood, from the description provided herein, that good thermal contact between the heating device and the chamber is needed as well as providing a uniform temperature distribution inside the chamber. It will be further recognized that the number of heating devices and the position of them is designed in such a way that the heating of the alloy is performed as efficiently and as uniformly as possible. The preheating of the process gas at the gas inlet side can be used to improve the uniform heating of the alloy. In addition to the heating device, the apparatus may also include insulation that may be placed around the chamber and thus enclosing the heating element(s) and the chamber in order to reduce heat loss from the chamber. Since this insulation material is not exposed to process gases at any time, any state of the art insulation material may be used.

The temperature may be controlled by a state of the art temperature controller. The temperature of the silicon alloy should be higher than 150° C., preferably higher than 300° C., in order to achieve a high production rate, and should not exceed 1100° C. A person skilled in the art will recognize that, if a gas mixture of hydrogen and HCl is used as an inlet gas, temperatures too high will shift the equilibrium reaction between silicon and hydrogen chloride gas on the one side and chlorosilanes on the other side in the direction of solid silicon. In the case when a pure copper-silicon alloy is used, the temperature should not exceed 800° C. since this marks the eutectic temperature of copper-silicon alloy. More preferably, the temperature should be kept in the range of 300 to 500 C in order to optimize the formation of trichlorosilane. It might be higher in the case of higher melting point metal-silicides used as feed stock. The temperature of the chamber may be controlled and/or monitored by thermocouples or any other kind of temperature sensor. The temperature sensors are preferably attached to the alloy however it will be understood that they are not required and that a person skilled in the art will be able to control the alloy temperature based on power consumption of the heating element(s).

The pressure in the reactor is controlled at above atmospheric pressure. In one embodiment the pressure is in the range of 1-10 bar. In another embodiment the pressure is approximately 5 bar.

In one embodiment, the alloy is placed inside the chamber in such a way that the alloy surface is well exposed to the gas stream. The alloy is preferably copper and lower purity silicon, e.g. metallurgical grade silicon. However, it will be understood that a higher purity silicon may also be used. The silicon concentration should be at least 10 at % in order to ensure a high silicon productivity. But lower silicon concentrations might be used as well without compromising the process in principle. In a preferred embodiment, the material used for the chlorination process is formed by eutectic or hypo-eutectic copper-silicon. Eutectic and hypo-eutectic copper-silicon is distinguished by a low affinity to oxidation when exposed to atmosphere. Further, may not swell or powder during the chlorination process. This can reduce the risk of particle contamination in the gas stream. Further, it can enhance the gettering of impurities, since the process gas can not penetrate into the bulk of the material, as it is the case for hyper-eutectic copper-silicon alloys due to the serious swelling of hyper-eutectic material. Additional additives may be added during the casting process of the alloy in order to accelerate the reaction time during the formation of chlorosilanes. Other additives that may be used include, but are not limited to, Chromium (Cr), Nickel (Ni), Iron (Fe), Silver (Ag), Platinum (Pt), and Palladium (Pd).

The silicon-metal alloy may be placed in the chlorination chamber in form of a fixed bed arrangement or in form of a travelling or any other kind of stirred bed configuration. Recharge of the silicon-metal alloy during the process might be provided using an additional port in the chlorination chamber.

The initial process gases that are used are gases that are operable to react to form a chemical vapour transport gas adapted for transporting silicon. In one embodiment, the initial process gases provide a source of chlorine. In one embodiment the initial process gases are hydrogen and dry HCl-gas which are fed into the chamber through the inlet, and the alloy is a copper-silicide alloy. The ratio of the hydrogen and dry-HCl-gas is in the range of 1:9 to 9:1, preferably in the range of 1:5 to 5:1 or more preferably in the range of 1:2 to 2:1. In the case of this embodiment, the gas mix coming out of the chlorination apparatus can be fed directly into a silicon deposition chamber.

Prior to the process beginning, the system is purged with dry, oxide-free gas or it is evacuated to provide an oxide-free atmosphere for the process.

Once supplied, the initial process gases react with the silicon at the surface of the silicon-metal alloy. As a result, chlorosilanes, for example trichlorosilane (TCS), silicontetrachloride (STC) or dichlorosilane (DCS), are generated by the reaction of the H2-HCl mixture with the silicon alloy. By way of this reaction a chemical vapour transport gas is provided for transporting silicon. In simplified form, the reaction can be written as follows:

Si+3HCl→SiHCl3+H2

Typical by-products of this reaction are SiH2Cl2 (DCS) and SiCl4 (STC).

The selectivity of the reaction is shifted in favour of TCS for lower temperatures of the silicon-metal alloy and towards STC for higher alloy temperatures.

The chlorosilanes are transported actively from the chlorination chamber into the deposition chamber. The deposition rate of silicon can be controlled by the flow rate (i.e. gas exchange rate) between the chlorination and the deposition chamber. The flow rate may be controlled by a control system that is connected to the apparatus and is configured to control the flow of gases within and to the chlorination and deposition chambers. Alternatively it can be controlled by the H2 to HCl ratio, or it can be controlled by the temperature of the filament. The deposition rate will also depend on the amount of silicon-metal alloy placed into the chlorination chamber.

As stated above, the gaseous silicon is then deposited on the heated filaments in the deposition chamber as high purity silicon. The types of filaments that may be used include, but are not limited to, silicon, graphite, molybdenum, tungsten or tantalum filaments. The filaments may be of any shape that allows for subsequent deposition of the silicon thereon. Preferably the filaments are U-shaped. The temperature of the filament is controlled and maintained in the range of 1000 to 1200 C. In simplified form, the decomposition looks like:

SiHCl3+H2→Si+3HCl

Typical by-products of this reaction are SiH2Cl2 (DCS) and SiCl4 (STC).

A more detailed discussion of the different chemical reaction and reaction steps is given for example in A. Luque and S. Hegedus (Eds.): “Handbook of Photovoltaic Science and Engineering”, Wiley & Sons Ltd, ISBN 0-471-49196-9. The reacted gases shown above are pumped back to the chlorination chamber, where they are used for the formation of chlorosilanes again. In such a way, a closed system is established which (a) minimizes the amount of process gases generated, (b) lowers the cost for the infrastructure for chlorosilane storage and transport, and (c) reduces the effort for waste gas treatment.

Since the process gases are circulating with transport rates per hour several times greater than the volume of the system, only a certain part of the chlorosilanes, mainly TCS, is reacting on the filaments within one cycle, the remaining amount goes back into the chlorination chamber.

In one embodiment, the deposition chamber is a Siemens type reactor with a bell-jar. The gas inlet and outlet as well as the electrical feed-throughs are incorporated into the bottom base-plate. It will be understood that the chamber wall should be cooled in such a way that an overheating of the wall is avoided.

In another embodiment, the gas inlet and outlet are positioned at the bottom and the top of the chamber, respectively. This arrangement provides a directed flow of the process gases.

In another embodiment, the deposition chamber is connected to the chlorination chamber in such a way that the two chambers are separated but are placed close together. In this embodiment, part of the dissipated heat from the filaments is used to support the active heating of the silicon-metal alloy, which improves the energy balance of the system.

It is further recognised that the composition of the produced chemical vapour transport gas from the reaction in the chlorination chamber is subsequently fed directly into the deposition chamber. It is recognised that there may be intermediate steps for chemical vapour transport gas filtration/treatment between the chlorination and deposition chambers, however at least a portion of the composition of the chemical vapour transport gas produced by the chlorination chamber is received by the deposition chamber (e.g. contaminates may be filtered out but the desired chlorosilane composition of the chemical vapour transport gas for deposition purposes is still received by the deposition chamber).

The present invention is not restricted to a specific chamber geometry, as long as the filament temperature can be adjusted to a temperature range of 1000° C. to 1200° C. and an appropriate flow of gases is provided to achieve deposition of silicon in amounts and purity levels as required. There is no restriction to the number of rods integrated into the deposition chamber, beside structural or design considerations.

In addition to the impurity gettering by the copper silicide, the apparatus may also include one or more additional components, for example, a condenser to catch volatile impurities, like e.g. metal chlorides (so called “salt trap”) or a particle filter that further reduce the impurity concentration in the deposited silicon.

A salt trap is characterized by an area with low flow velocity and large, cooled surface, which favors the condensation of volatile metal-chlorides with boiling points higher than the boiling temperature of the chlorosilane used for the transport of the silicon. The temperature inside the salt trap should not be lower than approx. 60° C. in order to avoid condensation of silicontetrachloride. The salt trap can be directly integrated into the gas loop or it can be installed in a by-pass loop in such a way that at a time only a portion of the gas stream is lead through the salt trap.

As a particle filter, any state of the art dust collector might be used as long as it is compatible with the corrosive atmosphere. Again, the filter might be integrated in the gas loop directly or might be installed in a by-pass loop.

In an alternate embodiment, the apparatus of the present invention also allows for the pre-processing or etching of the silicon-metal alloy in the chlorination chamber prior to the process gases entering the chamber. In this embodiment the deposition chamber is closed off to the chlorination chamber, i.e. any gases in the chlorination chamber are not able to flow through to the deposition chamber, and an appropriate etching gas mixture is fed into the deposition chamber. An example of the type of gas mixture that may be used includes H2 and HCl.

The present invention will now be discussed in further detail with reference to the accompanying Figures. In an illustrated embodiment a copper-silicide is provided as the initial source of silicon.

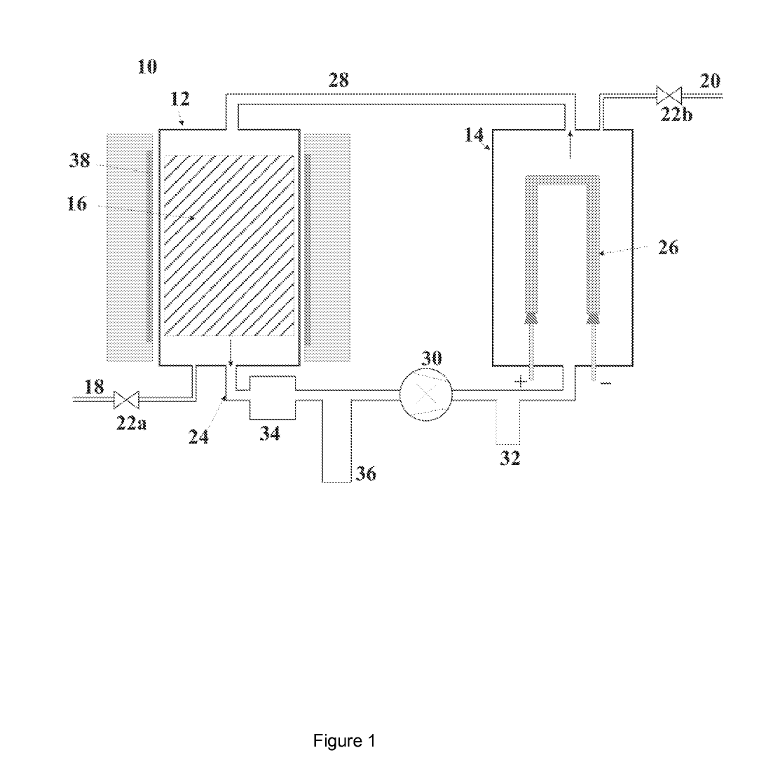

FIG. 1 shows a schematic cross-section of the apparatus, shown generally at 10, used for the generation of chlorosilanes from a silicon-metal alloy and the production of purified silicon according to a chemical vapor deposition (CVD) process. Chlorination takes place in a first vessel or chamber 12, deposition of high purity silicon is carried out in a second vessel or chamber 14. The vessels 12, 14 are manufactured from material that is impervious and resistant to the process gases. The alloy 16 is placed in the first vessel 12 in such a way that a maximum surface area is facing the gas stream. The initial gas mixture, e.g. H2 and HCl, is fed into the chambers via the inlet 18 and at the end of the process, the process gases are pumped out via the outlet 20 located in the second vessel 14. Valves 22a, 22b close the loop during the process.

The use of valves 22a or 22b allows also the sampling of process gases during the process for process gas analysis or the addition of a specific gas species or the variation of the H2 to HCl ratio.

Once the initial gas stream has entered vessel 12 the valve 22a is closed to ensure a closed loop system. It will be understood that valve 22b will have been closed prior to the initial gas stream being fed into vessel 12. Heat is then actively applied to the alloy 16 using a heating device 38, and when the temperature of the alloy is greater than 150° C. the initial gas source reacts at the surface of the alloy 16 to produce a gaseous source of silicon, i.e. chlorosilanes. The chlorosilane gas then exits the vessel 12 through outlet 24 to flow through to vessel 14.

In vessel 14 there is located at least one U-shaped filament 26 upon which silicon is deposited. The filament 26 is heated to a temperature in the range of 1000° C. to 1200° C. to allow for silicon deposition. The resulting gas containing mainly H2, HCl, TCS and STC then exits the vessel 14 through a second channel 28 to return to vessel 12. This gas then serves as an initial chlorine source and therefore no additional gas source is required beyond what is generated within the closed loop system. The STC, or part of it, will convert back to TCS, the HCl, or part of it, will react with the low purity silicon from the silicon-metal alloy to chlorosilane, mainly TCS. The gas is actively circulated throughout by a pump 30, the transport rate is measured by a flow meter 32. In a salt trap 34 at the exit of the chlorination chamber, volatile impurities condensate and are captured. Particles might be caught by a particle filter 36.

Since particles and metal-chlorides arise mainly from the chlorination chamber, the more favorable position for the particle filter and the salt trap is after the outlet of the chlorination chamber. However, it will be understood that these components are not required and the apparatus and method described herein will work without these components.

In addition, any state of the art blower or transport pump may be located between the two chambers provided that it can handle the corrosive gases.

The location of the inlet 28 and outlet 24 are shown as entering the vessel 12 from the top, for the inlet, and exiting vessel 12 from the bottom, for the outlet 24. However, the configuration of the inlet and outlet may be different from that depicted.

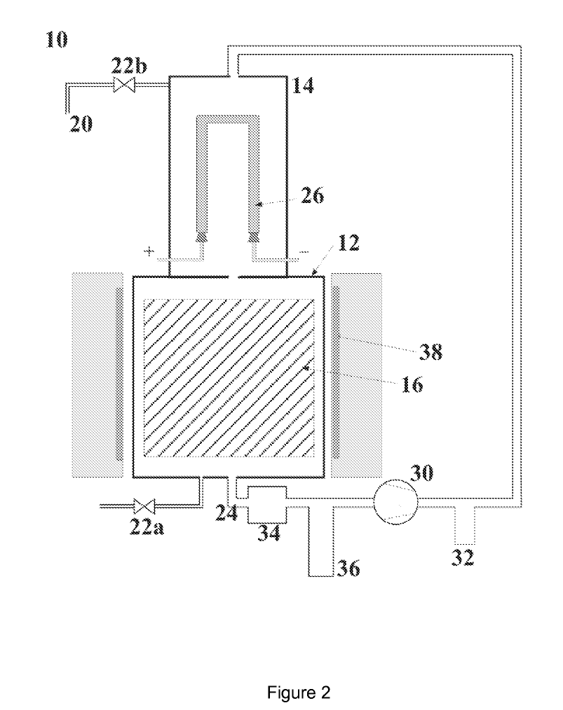

In FIG. 2, the deposition chamber 14 is attached to the chlorination chamber 12 in such a way that the hot gas leaving the deposition chamber is used to act as an additional heat source for the silicon alloy. Such an arrangement improves the energy efficiency of the system. It further shows that the size and the volume of the two chambers may be different, depending on the amount of alloy to be used or the amount of silicon to be deposited.

In both cases, i.e. in the fully detached arrangement or in the attached arrangement, guiding systems for the process gases may be implemented in one or both chambers in order to optimize the flow of gases within the corresponding chamber, not shown.

An analysis on the purity of deposited silicon formed by the method described herein, as well as the metallurgical grade silicon used to form the alloy, is provided in Table 1. Representative samples are displayed. All other elements not shown were beyond the detection limits. The silicon was analyzed by GDMS (Glow Discharge Mass Spectroscopy) by an independent, certified laboratory (NAL—Northern Analytical Lab., Londonderry, N.H.).

TABLE 1
Concentration of impurities in the deposited silicon, measured by GDMS.

| | m.g. silicon | Run3.2-7 | Run3.2-16.3 | Run3.2-17 |
|---|---|---|---|---|
| | ppmw | ppmw | ppmw | ppmw |
| B | 18 | 0.044 | 0.095 | 0.029 |
| Na | 0.1 | 0.06 | 0.071 | 0.059 |
| Mg | 0.7 | ≦0.01 | ≦0.01 | 0.011 |
| Al | 335 | 0.025 | 0.018 | 0.016 |
| P | 16 | ≦0.01 | 0.087 | ≦0.01 |
| S | 0.069 | ≦0.05 | ≦0.05 | ≦0.05 |
| Cl | 0.31 | <1 | <1 | <1 |
| K | 0.072 | 0.087 | 0.056 | 0.052 |
| Ca | 5.6 | ≦0.1 | ≦0.1 | ≦0.1 |
| Ti | 35 | <0.01 | <0.01 | <0.01 |
| V | 1.7 | <0.01 | <0.01 | <0.01 |
| Cr | 8.7 | ≦0.02 | ≦0.02 | ≦0.02 |
| Mn | 55 | <0.05 | <0.05 | <0.05 |
| Fe | 2800 | 0.02 | 0.036 | 0.032 |
| Co | 1.3 | <0.01 | <0.01 | <0.01 |
| Ni | 7.1 | ≦0.05 | ≦0.05 | ≦0.05 |
| Cu | 24 | ≦0.1 | ≦0.1 | ≦0.1 |
| As | 0.065 | <0.2 | <0.2 | <0.2 |
| Zr | 4.5 | <0.01 | <0.01 | <0.01 |
| Nb | 0.17 | <0.05 | <0.05 | <0.05 |
| Mo | 0.71 | <0.1 | <0.1 | <0.1 |

The following examples are provided to further describe the method and the performance of the apparatus of the present invention. These are examples only and are not meant to be limiting in any way.

### Example 1

A chlorination chamber of 34 cm diameter and 50 cm height was charged with 25 bricks of silicon-copper alloy, the total weight of the alloy was 12 kg, the concentration of silicon was 30 wt % or 3.6 kg. The bricks were placed equally spaced in the center of the chlorination chamber. After proper evacuation and filling the chamber with process gases, the chlorination chamber was connected to a Siemens type poly-silicon deposition chamber. The pressure in the chamber was maintained at above atmospheric pressure. The alloy was heated to a temperature of 300° C. to 400° C. and the process gases were circulated in a closed loop system between the chlorination and the deposition chamber. The chlorosilanes, (mainly trichlorosilane), which had been generated in the chlorination chamber, were consumed in the deposition chamber, and the exhaust gases (especially enriched with HCl and STC) from the deposition process were used to generate new chlorosilanes by reacting with the silicon-alloy. The gases circulated for 48 hours, during which time 1.6 kg of silicon had been extracted from the silicon-copper-alloy and had been deposited in the deposition reactor. No copper was detected in the deposited silicon, the silicon was analyzed by GDMS (Glow Discharge Mass Spectroscopy) by an independent, certified laboratory (NAL—Northern Analytical Lab., Londonderry, N.H.). The resolution limit for copper was 50 ppb, clearly indicating that the copper stays in the solid phase and only the silicon is going into the gas phase and is extracted from the alloy. The alloy bricks, which had been inserted in the form of solid pieces, formed a porous, rather spongy material, which allows a good gas exchange, even when the silicon has to be extracted from the inner areas of the alloy bricks. After the process was stopped and the reactor was cooled down, the gases were replaced by inert gas.

### Example 2

Four pieces of silicon copper-alloy (total weight: 1.3 kg, amount of silicon: 390 g) were placed in a chlorination chamber of 15 cm diameter and 25 cm height. The alloy was heated by an external heating device, the process gases were circulated by an external membrane pump. Inside the deposition chamber, a silicon filament was placed, which was heated to 1100° C. and which consumed the produced chlorosilanes. The chlorination and the deposition chamber had been constructed in an attached arrangement, using part of the filament heat to heat the silicon-copper alloy. The deposition chamber was separated from the chlorination chamber by an intermediate plate (built of quartz disks and a copper plate). A center hole allowed for good gas exchange. Metallurgical grade silicon with a purity of 99.3% had been used for the alloy casting. Within 30 hours, 210g of silicon had been deposited on the hot filament. According to GDMS measurements (average of two measurements taken from different areas of the deposited silicon), the total amount of metallic impurities was below 250 ppb (in detail: Al: 20 ppb, Mg: 5 ppb, Ca: 45 ppb, Fe: 21 ppb, Na: 56 ppb, K: 54 ppb, all other metals: below the detection limit). The boron concentration was 0.22 ppm and the phosphor concentration was below the detection limit (<10 ppb).

### Example 3

10 kg of chunks with approx. 1 ccm size were placed in a chlorination chamber of 34 cm diameter and 50 cm height. The chunks had been formed of copper-silicon alloy with a silicon concentration of 30 at %. Within 38 h, 2 kg of purified silicon was deposited on 2 10×10 mm filaments of 34 cm height. Deposition temperature was 1100° C. The impurity analysis is provided in table 1, “Run 3.2-17”.

### Example 4

28 kg of eutectic copper-silicon (Si-concentration 16% tw) 16 were placed in a chlorination chamber 12 in form of 88 bricks. The chamber 12 was connected to a silicon deposition reactor 14 in order to consume the produced chlorosilanes and to provide the system with fresh HCl, generated during the deposition process. Within 77 hours, 3.1 kg of silicon had been extracted from the eutectic copper-silicon and transferred into the gas form and deposited on a heated silicon filament (filament temperature: 1050-1100 C). The eutectic copper-silicon was heated to a temperature of 350 to 450 C. The initial gas composition which was fed into the chlorination chamber was a mixture of H2 and HCl (60% H2 and 40% NCl). During the process, the chlorination chamber was fed only with the off-gas from the deposition reactor. After the process, the integrity of the eutectic copper-silicon plates was fully given, no swelling or powdering of the plates was observed. The purity of the deposited silicon was analyzed by GDMS: boron and phosphorous were below the detection limit of 10 ppb. As metallic impurities, only Na, K, Al and Fe had been detected, all other metals were below the detection limit of GDMS. In total, the amount of detectable metallic impurities was <100 ppb.

### Example 5

54 kg of hypo-eutectic (pure eta-phase, Si-concentration 12% wt) copper-silicon 16 was placed in a chlorination chamber 12 in form of 110 bricks. Temperature during the chlorination process was in the range of 270 to 450 C. The chamber 12 was connected to a silicon deposition reactor 14 in order to consume the produced chlorosilanes and to provide the system with fresh HCl, generated during the deposition process. Within 117 hours, 4 kg of silicon had been extracted from the hypo-eutectic copper-silicon and transferred into the gas form and deposited as poly-silicon on heated silicon filaments. Filament temperature was 1050 to 1100 C. Rod morphology was very smooth, no pop-corn growth or morphological instabilities were observed. The initial gas composition which was fed into the chlorination chamber was a mixture of H2 and HCl (60% H2 and 40% HCl). During the process, the chlorination chamber was fed only with the off-gas from the deposition reactor. After the process, the integrity of the hypo-eutectic copper-silicon bricks was fully given, no swelling or powdering of the bricks was observed

### Example 6

1.4 kg of a Ni—Si alloy with a nickel concentration of 60% were placed in a chlorination reactor 12 and heated to 350 to 450 C. Over a period of 27 hours, 67 g of silicon was extracted from the nickel-silicon alloy and deposited on heated silicon filaments. During the process, the nickel-silicon alloy did not change its shape and did not show any indication of swelling, powdering or release of particles.

### Alternative Embodiment of the Apparatus 10 and Related Process 8

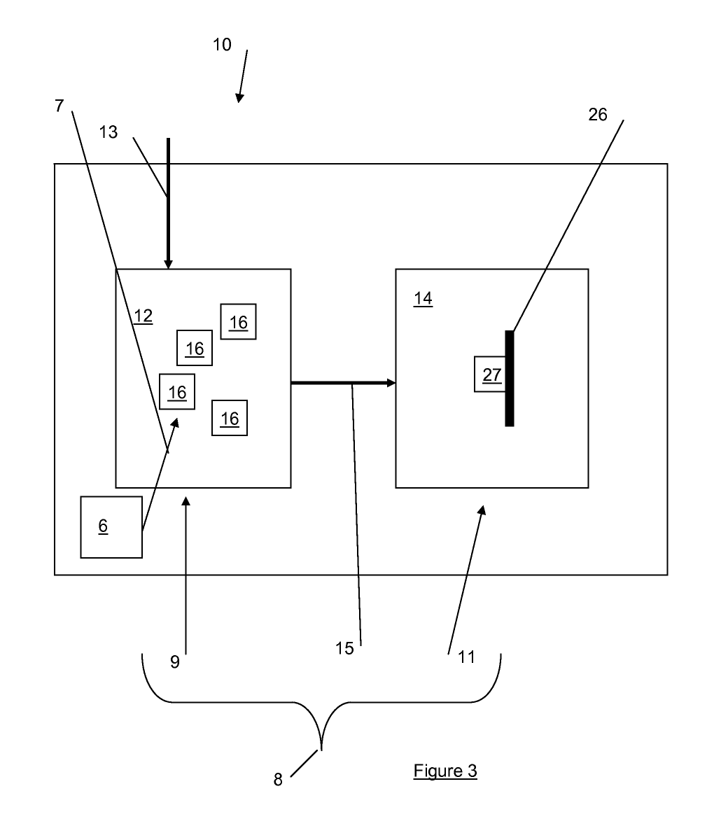

Referring to FIG. 3, the present relates to a method 8 of producing high purity silicon 27. In particular, the present relates to a method 8 of producing high purity silicon 27 from lower-grade source material 16. The present further provides a source 16 for the production of chlorosilanes 15. In particular, the present provides a method for the production of chlorosilanes 15 from eutectic or from hypo-eutectic silicon-metal alloys 16. The present also relates to the production of high purity, cost efficient silicon 27. This high purity silicon 27 may be useful, for example, as base material for forming multi-crystalline or single crystalline ingots for wafer manufacturing. Further, the present further relates to the refining of raw silicon, for example, metallurgical grade silicon (approximately 98-99% purity), into high purity silicon having a purity with a selected resistivity above a resistivity threshold (e.g. of about 50 Ohm-cm or greater).

### Process 8 and Apparatus 10

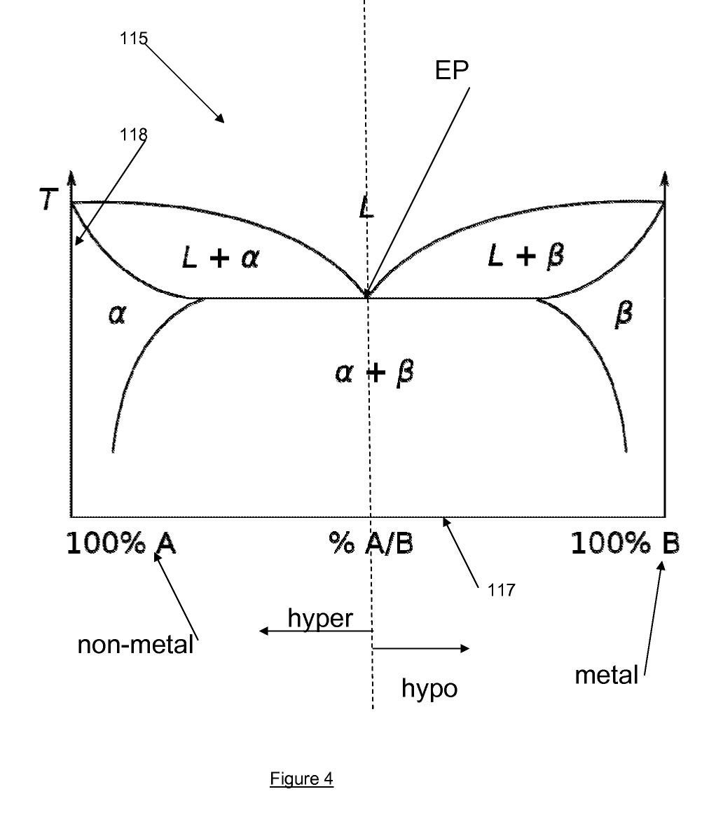

In general, the melting point of a mixture of two or more solids (such as a metal silicon alloy material 16, hereafter referred to as alloy material 16) depends on the relative proportions of its constituent elements A,B, see FIGS. 4,5. Further to the below, alloy material 16 is selected to facilitate the formation of chemical vapour, e.g. chlorosilanes, from a copper-silicon compound or other silicon-metal alloy of selected composition including selected degree of eutectic property.

Referring to FIG. 3, provided is an alloy material 16 for example use as a source for the production of chlorosilane containing transport gas 15. Described is a general method for the production of chlorosilanes 9 (in the transport gas 15) from eutectic and/or hypo-eutectic metal-silicon alloy material 12, as well as the general desired properties of the alloy material 16 and examples of the alloy material 16 production, use in an example chlorination-deposition process 8, and recycling. It is recognized that the following description provides for a metal/silicon alloy material 16 with desirable properties for use in CVD process 8 implemented in a CVD apparatus 10, for example. The following examples of the CVD process 8 and corresponding apparatus 10 are described as chlorination 9-deposition 11 for discussion purposes only. It is contemplated that CVD process 8 (including vapour production 9 and deposition 11) and corresponding apparatus 10 other than directed to chlorination can also be used with the alloy material 16, as desired. It is recognized that chlorosilanes are one example of the transport gas 15 produced as a result of reaction of the silicon in the alloy material 16 with the input gas 13 (e.g. containing HCl). Other examples of the transport gas 15 can include other halides (e.g. containing reactive forms of fluorine, bromine, and/or iodine, etc, with silicon-HBr, HI, HF, etc.). Accordingly, certain modifications with respect to the temperature, the gas composition, the pressure, and/or other related process 9,11 parameters could be required due to the different boiling points of the hydrogen halides and the different reactivities between the input gas(es) 13 and the silicon of the metal silicon alloy material 16. Further, compatibility with certain materials used for the process 9,11 or during the process 9,11 has to be provided for.

Examples of CVD are such as but not limited to: classified by operating pressure; classified by physical characteristics of vapor; plasma methods; Atomic layer CVD (ALCVD); Hot wire CVD (HWCVD); Hybrid Physical-Chemical Vapor Deposition (HPCVD); Rapid thermal CVD (RTCVD); and Vapor phase epitaxy (VPE). The operating pressure and/or temperature of the transport gas generation process 9 can be selected so as to be compatible with (i.e. facilitate) the formation of the transport gas 15, be compatible with the melting point of the alloy material 16 (e.g. the temperature of the process 9 is below the melting point temperature of the alloy material 16), and/or be compatible and/or otherwise facilitate the diffusion of silicon through the matrix 114 in preference (e.g. greater than—for example at least twice as much, as least four times as much, at least an order of magnitude as much, as least two orders of magnitude as much) the diffusion of any impurities contained in the alloy material 16.

In general, Chemical Vapor Deposition (CVD) is a chemical process 8 used to produce high-purity, high-performance solid materials 27 such as deposited silicon 27 of a desired purity. The process 8 (e.g. including chlorination 9-deposition 11 processes) can be used in the semiconductor and solar industries to produce the silicon 27 of desired purity and shape. In a typical CVD process 8, a silicon substrate 26 (e.g. filament such as a wafer or shaped rod) is exposed to one or more volatile precursors (i.e. obtained from transport gases 15 produced by the chlorination process 9) to facilitate the deposition process 11 of the silicon 27 onto the substrate 26. Accordingly, in the deposition process 11 the chlorosilanes in the process gas 15 reacts and/or otherwise decomposes on the substrate 26 surface to produce the desired deposited silicon 27.

Further, the process 8 can also be used for the production of high purity, cost efficient silicon 27, such as applied to the refining of raw silicon, for example, but not limited to, metallurgical grade silicon of approx. 98 to 99.5% purity provided as a component of the metal/silicon alloy material 16, into high purity silicon 27 having a purity with respect to metallic impurities better than a selected purity level (e.g. 6N). The process 8 can also be used for the refining and production of solar grade silicon 27 which can be used, for example, as base material for forming multi-crystalline or single crystalline ingots for wafer manufacturing.

Referring again to FIG. 3, input gases 13 (e.g. providing a source of chlorine including hydrogen gas and dry HCl-gas) are directed into a chemical vapour producing (e.g. chlorination) region 12 (e.g. chamber) of the vapour-deposition (e.g. chlorination-deposition) apparatus 10 in order to come into contact with the alloy material 16 (e.g. copper-silicide alloy). The input gases 13 are gases that are operable to react with the alloy material 16 to form the chemical vapour transport gas 15 for transporting silicon from the alloy material 16 in the vapour production region 12 (e.g. chamber or portion of a chamber) to a deposition region 14 (e.g. chamber or portion of a chamber) of the apparatus 10.

As an example of the above, process 8 and apparatus 10 provides for the refinement of silicon via the production of chlorosilanes containing transport gas 15, and the deposition of high purity silicon 27 on a silicon filament 26. The chlorosilane gas 15 is formed 9 in the one region 12, in which the lower purity silicon is placed in the form of the silicon alloy material 16, and higher purity silicon 27 is deposited 11 in the other region 14, where heated silicon filament(s) 26 are located. The use of the term chlorosilanes herein refers to any silane species having one or more chlorine atoms bonded to silicon. The produced chlorosilanes may include, but are not limited to, dichlorosilanes (DCS), trichlorosilanes (TCS) and silicon tetrachloride (STC). For example, TCS is used for the deposition of the purified silicon 27.

Further, the above-described process 8, use of the alloy material 16 can facilitate the removal of metal impurities from the deposition process 11. In particular, the deposition method can provide high purity silicon 27 with the removal of metallic impurities that are resident in the alloy material 16. Some metallic impurities do not form volatile chlorides, like e.g. Fe, Ca, Na, Ni, or Cr and thus stay with the alloy material 12 in the chlorination region 12. Others, which form chlorides with a rather low boiling point (e.g. Al or Ti), will evaporate, but do more preferably condensate on cold surfaces than being deposited on the hot silicon filament 26 in the deposition region 14.

### Example CVD Process 8 Parameters

Once the input gas stream 13 has entered region 12, heat 7 can be actively applied/supplied to the alloy material 16 using a heating device 6, and when the temperature of the alloy material 16 is greater than a selected temperature T (e.g.150° C.) the input gas reacts at the surface of the alloy material 16 to produce a gaseous source of silicon, i.e. chlorosilanes transport gas 15. The chlorosilane gas 15 then exits the region and is directed to the region 14.

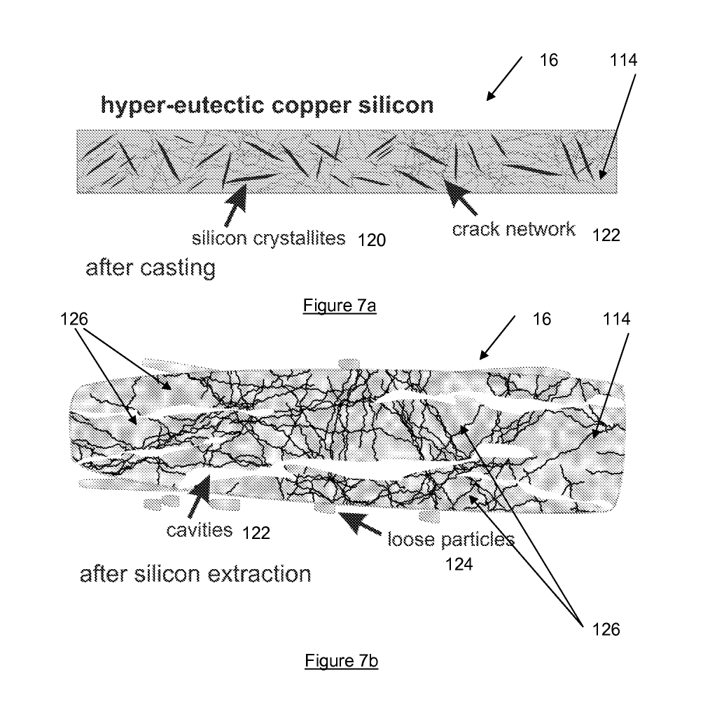

In region 14 there is located at least one shaped (e.g. U-shaped) filament 26 upon which silicon 27 is deposited. The filament 26 is heated to a temperature in the range of 1000° C. to 1200° C. to allow for silicon deposition 11. To form the silicon-metal alloy material 16 used in the apparatus 10 and process 8 using the selected percent weight of silicon such that the presence (if any) of crystallites 120 (see FIG. 7a) in the alloy material 16 is at or below a selected maximum crystallite threshold (it is recognised that for silicon at or below the eutectic silicon % wt composition—eutectic or hypo eutectic matrix 114—the presence of crystallites 120 in the alloy material 16 should be negligible if any), any metal might be used, provided that the metal has a vapour pressure lower than a defined vapour pressure threshold and shows/exhibits a limited reaction with HCl gas and hydrogen. In the case of copper silicon alloy material 16, the maximum crystallite threshold can be defined as a percent weight of silicon in the alloy material 16 as less than 20%, less than 19%, less than 18%, less than 17.5%, less than 17%, or less than 16.5%, for example.

Further, for example, the metal should not form a gaseous species which tends to decompose on the hot filaments 26 in the deposition region 14. Preferably the metal used does not form a volatile metal-chloride in the range of the working temperature of the chlorination region 12. Potential alloy material 16 forming metals include, but are not limited to, copper, nickel, iron, silver, platinum, palladium, chromium or combinations of these metals. In a preferred embodiment of the present invention the alloy material 16 is a silicon-copper alloy.

As a result, chlorosilanes gas 15, for example trichlorosilane (TCS), silicon tetrachloride (STC) or dichlorosilane (DCS), is generated by the reaction 9 of the H₂—HCl mixture 13 with the silicon alloy material 16. By way of this reaction 9 the chemical vapour transport gas 15 is provided for transporting silicon. In simplified form, the reaction 9 can be written as follows:

Si+3HCl→SiHCl₃+H₂

Typical by-products of this reaction can be SiH₂Cl₂ (DCS) and SiCl₄ (STC).

The chlorosilanes gas 15 is transported actively from the chlorination region 12 into the deposition region 14. The deposition rate 11 of silicon 27 can be controlled by a flow rate (i.e. gas exchange rate) between the chlorination and the deposition regions 12,14. The flow rate may be controlled by a control system that is connected to the apparatus 10 and is configured to control the flow of gases 13,15 within and to the chlorination and deposition regions 12,14. Alternatively flow rate can be controlled by the H₂ to HCl ratio or other ratio of the input gases 13, or flow rate can be controlled by the temperature of the filament 26. The deposition rate 11 can also depend on the amount of silicon-metal alloy material 16 placed into the chlorination region 12, the temperature T of the alloy material 16, and/or the % wt of silicon in the alloy material 16.

As stated above, the gaseous silicon in the transport gas 15 is then deposited on the heated filaments 26 in the deposition region 14 as high purity silicon 27. The types of filaments 26 that may be used include, but are not limited to, silicon, graphite, molybdenum, tungsten or tantalum filaments. The filaments 26 may be of any shape that allows for subsequent deposition 11 of the silicon 27 thereon. The temperature of the filament 26 is controlled and maintained in the range of 1000 to 1200 C. In simplified form, the decomposition 11 looks like:

SiHCl₃+H₂→Si+3HCl

Typical by-products of this reaction 11 are SiH₂Cl₂ (DCS) and SiCl₄ (STC).

Further, the silicon-metal alloy material 16 may be placed in the chlorination region 12 in form of a fixed bed arrangement or in form of a travelling or any other kind of stirred bed configuration. Recharge of the silicon-metal alloy material 16 during the process 9 might be provided using a recharge port in the chlorination region.

### Structure of Metal-Silicon Alloy Material 12

In general, the melting point of a mixture of two or more solids (such as a metal-silicon alloy material 16, hereafter referred to as alloy material 16) depends on the relative proportions of its constituent elements A,B, see FIGS. 4,5. It is recognized that the alloy material 16 is such that the predominant/major constituent element(s) B are metal (e.g. copper Cu, nickel Ni, iron Fe, silver Ag, Platinum Pt, Palladium Pd, chromium Cr and/or a combination thereof) and the minor constituent element A includes silicon Si. Accordingly, metal silicon (Si) alloy material 16 can be characterized as a metal/silicon alloy in which the silicon occupies a minor volume fraction (e.g. 10-16%) of the alloy structure 114 as compared to the volume fraction of the metal (e.g. Cu).

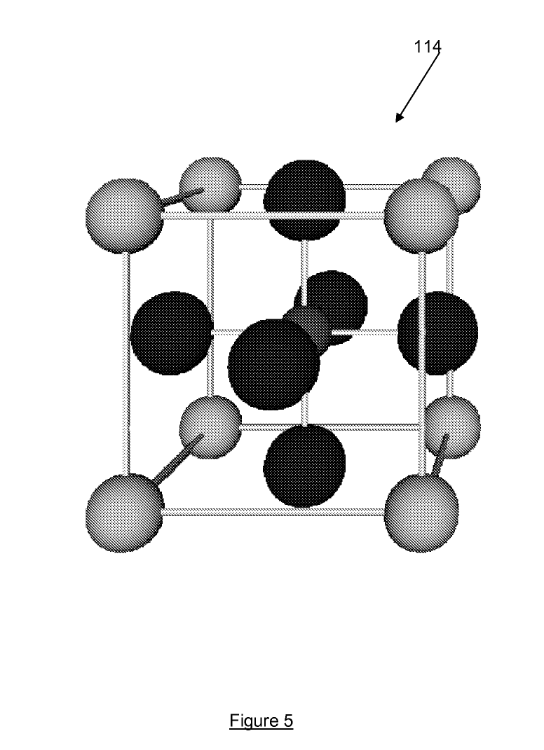

An eutectic or eutectic alloy material 16 is a mixture at such proportions that the melting point is a local temperature T minimum, which means that all the constituents elements A,B crystallize simultaneously at this temperature from molten liquid L solution. Such a simultaneous crystallization of an eutectic alloy material 16 is known as an eutectic reaction, the temperature T at which it takes place is the eutectic temperature T, and the composition and temperature of the alloy material 16 at which it takes place is called the eutectic point EP. In terms of the alloy material 16, this can be defined as a partial or complete solid solution of one or more elements A,B in a metallic matrix/lattice 114 (see FIG. 5). Complete solid solution alloys give a single solid phase microstructure, while partial solutions give two or more phases that may be homogeneous in distribution depending on thermal (heat treatment) history. It is recognized that the alloy material 16 has different physical and/or chemical properties from those of the component elements A,B. In terms of matrix/lattice 114, this can be defined as a defined ordered constituents A,B structure (e.g. crystal or crystalline) of solid material, whose constituents A,B as atoms, molecules, or ions are arranged in an orderly repeating pattern extending in two and/or all three spatial dimensions.

Eutectic or hypo-eutectic metal-silicon alloys 16 may be distinguished from hyper-eutectic alloys in that the eutectic or hypo-eutectic alloys 16 do not demonstrate silicon microcrystal 120 formation when the cast alloy is cooling, as would be observed in the case of hyper-eutectic alloys. This lack of microcrystals 120 can provide an advantage when the eutectic or hypo-eutectic silicon-copper alloy 16 is used as source material 16 for the process 8 described herein, for example.

Referring to FIG. 4, shown is an example equilibrium phase diagram 115 for a binary system comprising a mixture of two solid elements A,B, where the eutectic point EP is the point at which the liquid phase L borders directly on the solid phase α+β. Accordingly, the phase diagram 115 plots relative weight concentrations of the elements A and B along the horizontal axis 117, and temperature T along the vertical axis 118. The eutectic point EP is the point at which the liquid phase L borders directly on the solid phase α+β (e.g. a homogeneous mixture composed of both A and B), representing the minimum melting temperature of any possible alloy of the constituent elements A and B. It is recognized that the phase diagram 115 shown is for a binary system (i.e. constituents A,B), however it is contemplated that other systems (e.g. tertiary A,B,C and higher) can be used to define the alloy material 16, such that Si is for example included in the minor constituent element A in combination with metal (or a mixture of different metals) as the major constituent element (or element group) B (e.g. Si is the minor constituent element A as compared to the major constituent element/element group comprising one or more different metals “B”. Examples of the alloy material 16 are alloys such as but not limited to: silicon-copper alloy; silicon-nickel alloy; silicon-iron alloy; silicon-silver alloy; silicon-platinum alloy; silicon-palladium alloy; silicon-chromium alloy; and/or a combination thereof (e.g. Cu—Ni—Si alloy). Further, it is recognized that the alloy material 16 can be a hypoeutectic alloy in which the percent weight (wt %) composition of the silicon constituent(s) A is to the left hand side of the eutectic point EP on the equilibrium diagram 115 of a binary eutectic system (i.e. those alloys having a percent weight (wt %) composition of the silicon A less than the eutectic percent weight (wt %) composition of the silicon A. Accordingly, at any position where the hypoeutectic alloy exists the solute (i.e. silicon A) concentration at that position is less than the solute (i.e. silicon A) concentration at the eutectic point EP. Further, it is recognized that the alloy material 16 can be a hypereutectic alloy in which the percent weight (wt %) composition of the silicon constituent(s) A is to the right hand side of the eutectic point EP on the equilibrium diagram 115 of a binary eutectic system (i.e. those alloys having a percent weight (wt %) composition of the silicon A greater than the eutectic percent weight (wt %) composition of the silicon A. Accordingly, at any position where the hypereutectic alloy exists the solute (i.e. silicon A) concentration at that position is greater than the solute (i.e. silicon A) concentration at the eutectic point EP. Hyper eutectic alloy materials 16 are considered multi-phase (e.g. two phase) alloys (e.g. heterogeneous) while hypo eutectic alloy materials 16 are considered single phase (e.g. one phase) alloys (e.g. homogeneous).

It is recognised that the eutectic or hypo-eutectic silicon-metal alloy 16 can have resistance to cracking 122 as the cast alloy cools, which is due, at least in part, to the substantial absence of silicon microcrystals 120 in the source material 16 (see FIG. 7a,b). The reduction in cracking 122 can inhibit access of ambient air and moisture to the interior of the cast piece 16, and thus can reduce absorption of oxygen and/or moisture once the cast alloy 16 is exposed to the ambient atmosphere. This may enhance the shelf-life of the cast alloy 16. Further, the release of oxygen or other impurities introduced in to the alloy material 16 (due to degradation by exposure to ambient conditions) into the chlorination region 12 can be reduced, thereby helping to improve the purity of the chlorosilane mixture in the process gas 13 and helping to improve the purity of the deposited silicon 27, for example.

### Metal-Si Alloy Material 16

It is recognised that different metal silicon alloy materials may be useful in the apparatus 10 for transport gas 15 production and silicon 27 deposition. For example, nickel silicon, platinum silicon, chromium silicon, and/or iron silicon may be useful alloy materials, wherein the metal silicon alloy materials 16 are designed such that the percent weight of silicon in the alloy material 16 is selected to be approximately at or below the eutectic composition. It is recognised that the percent weight of silicon in the metal silicon alloy material 16 is chosen so that the amount of silicon crystallites 120 is at or below a specified maximum crystallite threshold. It is recognised that any silicon percent weight in the alloy material above the specified maximum crystallite threshold would introduce crystallites 120 of sufficient number, size, and/or distribution that would be detrimental to the structural integrity of the alloy material due to incompatible/dissimilar thermal expansion properties of the crystallites 120 and the eutectic matrix 114. As already discussed, the presence of crystallites 120 in the alloy material 16 is detrimental to the structural integrity of the alloy material due to the cracks 122 that develop due to the presence of the crystallites 120 of sufficient number, size, and/or distribution that are above the specified maximum crystallite threshold.

It is also recognised that the metal silicon alloy material 16 can have two or more metals in the matrix 114, such as any combination of two or more metals selected from the group including copper, nickel, chromium, platinum, iron, gold, and/or silver, etc. Further, it is recognised that copper of the metal silicon alloy material 16 could be the largest percent weight out of all the other alloy constituents (for example in the case of two or more metals) including silicon.

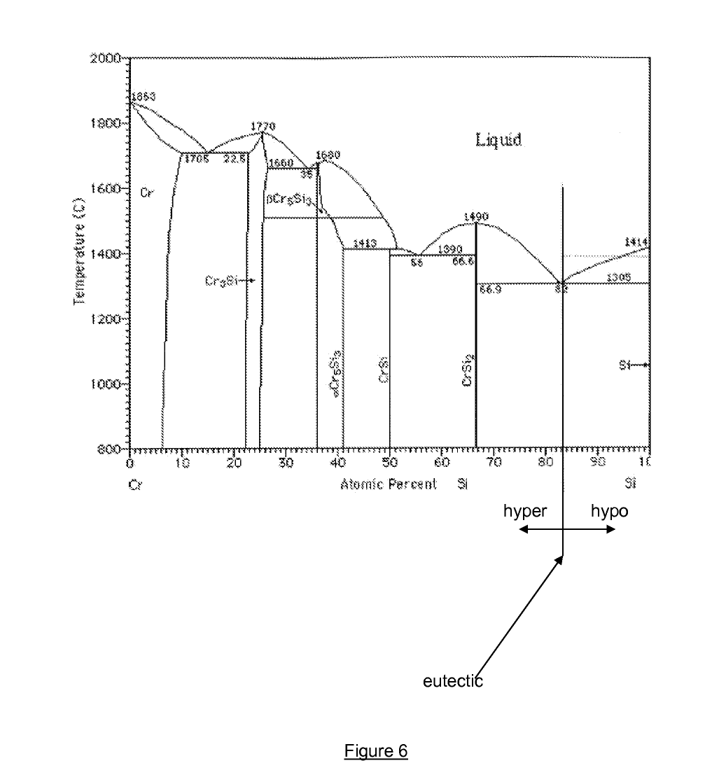

Referring to FIG. 6, shown is example eutectic properties and ranges for the metal chromium silicon alloy material 16.

### Cu—Si Alloy Material 16 Examples

A further example of the alloy material 16 is copper Cu and silicon Si that form a rather complex phase diagram 115, at least one eutectic point EP is known (Si is approximately 16% wt, Tm=800 C) and several intermetallic phases are formed. The most prominent of the intermetallic phases is the eta-phase, which consists of Cu3Si (with a certain phase width, depending on the temperature). The melting point of the intermetallic Cu3Si phase has been reported to T=859 C. In the hyper-eutectic range (e.g. Si-concentration greater than approximately 16% wt) copper Cu and silicon Si are completely miscible in the liquid over the whole concentration range up to pure silicon Si, but during cooling down, silicon Si crystallizes in form of interspersed crystallites 120 (needles or plates of multiple millimeter length), which are embedded in the matrix 114 of the eutectic alloy material 16. In the concentration range below the eta-phase (i.e. hypo-eutectic composition with Si less than approximately 16% wt), at least 5 additional intermetallic compounds are known, but most of them have been identified only for the high temperature range.

In any event, it is recognized that the Cu—Si alloy material 16 can be defined as eutectic alloy material 16 for Si in the range of approximately 16% wt, hyper eutectic alloy material 16 for Si in the range of approximatley 16% wt to 99% wt, and hypo eutectic alloy material 16 for Si in the range of 1% wt to approximately 16% wt. As further described below, the Cu—Si alloy material 16 for use in the chlorination chamber 12 of the chlorination-deposition system 10 Si can be of a percent weight less than the eutectic point EP in the range such as but not limited to; 1-16%, 4-16%, 5-16%, 6-16%, 7-16%, 8-16%, 9-16%, 10-16%, 11-16%, 12-16%, 13-16%, 14-16%, 1-15%; 4-15%, 5-15%, 6-15%, 7-15%, 8-15%, 9-15%, 10-15%, 11-15%, 12-15%, 13-15%, 14-15%, to restrict or to otherwise inhibit the formation of the silicon crystallites 120 (i.e. free silicon) as silicon in the alloy material 16 that is outside of the matrix/lattice 114. It is recognised that the crystallites 120 can be considered precipitates formed outside of the Cu—Si matrix 114 (i.e. the excess silicon—greater than approximately 16% wt—is insoluble in the Cu—Si matrix 114 and therefore forms the crystallites 120 outside of the matrix 114)

For example, it is recognized that for hypo-eutectic alloy material 16 at about 12% wt silicon, there is effectively little to no free silicon (i.e. crystallites 120) in the alloy material 16. As the % wt of the silicon approaches that of the eutectic point EP (e.g. approximately 16% wt), there can be up to 4% wt native silicon that is composed in atomic strings contributing to a homogeneous alloy mixture (i.e. the native silicon is dispersed in the eutectic structure 114, such that the alloy mixture can be considered a single phase homogeneous mixture). As one exceeds the % wt of the silicon for the eutectic point EP (e.g. approximately 16% wt), excess silicon solidifies as pure silicon crystallites 20 dispersed as one phase of a multi-phase heterogeneous mixture (i.e. comprising the eutectic material 114 and the silicon crystallites 120). Accordingly, the alloy material 16 having % wt of the silicon less the % wt silicon for the eutectic point EP (e.g. approximately 16% wt) can be considered a single phase alloy material 16.

In terms or homogeneous versus heterogeneous, a homogeneous mixture has one phase although the solute A and solvent B can vary. Mixtures, in the broader sense, are two or more substances physically in the same place, but not chemically combined, and therefore ratios are not necessarily considered. A heterogeneous mixture can be defined as a mixture of two or more mechanically dividable constituents.

Let's consider, for example, two pure copper-based alloy materials 16, the first alloy material 16 with a hypo eutectic silicon content of 7%, the second with a hyper eutectic silicon content of 22%. The cooling speed of the alloy liquid is assumed to be low to allow an equilibrium to be established between the phases by short-time diffusion during solidification. The structure of the hypoeutectic alloy material 16 is comprised of the network of fine eutectic Si dispersed in the pure copper matrix 114. On the contrary, after the hypereutectic alloy material 16 has cooled, the material structure consists of primary silicon crystals 120 dispersed as a different phase to that of the eutectic phase as the matrix 114 that comprises pure copper and eutectic Si.

Further, it is recognised that for copper containing alloy material 16, the presence of copper combined atomically with silicon or other elements (e.g. bonded with silicon in the matrix 114) at the external surface of the alloy material 16 provides for facilitating the reaction of the silicon with the input gas 13 to generate the transport gas 15 (e.g. the presence of atomically bonded copper acts as a catalyst for the reaction between silicon and the input gas 13). Further, it is recognised that since the copper is in the matrix 114, rather than in free form (e.g. pure copper), the inclusion of copper in the transport gas 15 as an impurity can be inhibited.

Advantages for Alloy Material 16 Other than Hyper Eutectic

It is recognized that alloy material 16 described as hyper eutectic refers to the presence of multi-phase alloy having the eutectic material phase 114 and the silicon crystallites 120 (e.g. Si crystallites 120).

Referring to FIGS. 7a,b, as described earlier, in the case of hyper-eutectic alloy materials 16, larger grain-sized silicon crystallites 120 are interspersed throughout the eutectic matrix 114 component/phase of the alloy material 16. This heterogeneous multi-phase alloy mixture has significant consequences for the further use and behavior of the alloy material 16 both inside and outside of the chlorination-deposition system 10. For example, during the casting process of the alloy material 16, e.g. making of the alloy material 16 for subsequent use in the system 10, first the silicon crystallites 120 are formed and they are embedded in the matrix 114 of eutectic metal-silicon. The silicon crystallites 120 have a different thermal expansion coefficient compared to the matrix 114 of eutectic metal-silicon, which can result in the formation of cracks and micro-cracks 122 in the matrix 114 of eutectic metal-silicon during the cooling down of the alloy material 16 from the eutectic solidification point (e.g. Tm=800 C for Cu—Si) to room temperature during the casting process. These micro-cracks 122 can result in an ongoing oxidation of the cast alloy material 16, as long as it is not stored in inert atmosphere for example. Under normal atmosphere, the shelf-time of the alloy material 16 can be limited and can result in decomposition and disintegration of the cast pieces of the alloy material 16 after a certain period of time.

Further, the elevated oxygen levels in the hyper-eutectic alloy material 16 due to the continuous oxidation can result in increased oxygen concentrations in the deposited high purity silicon 27 (obtained from the alloy material 16 during the chlorination-deposition process 8. Further, during the exposure to the input gas 13 under normal operational temperatures in the chlorination region 12 of the chlorination process 9, the hyper-eutectic metal-silicon material 16 can swell (e.g. expand due to thermal expansion and/or penetration of the input gas 13 into the alloy material 16 via the cracks 122) and it has been found that the volume of the alloy material 16 can increase by approximately a factor of 2. Further, the expansion of the alloy material 16 can form smaller pieces 124,126 such that the physical form of the alloy material 16 can degenerate into a spongy, rather unstable material form, which can easily fall apart (i.e. powder) upon repeated exposure to the chlorination process gas 13 and associated chlorination temperatures T of the chlorination process 9. The swelling/decomposing of the hyper-eutectic alloy material 16 can also lead to the formation of dust and particles 124 in the chlorination-deposition system 10, which may be transported by the gas stream 15 and can affect the purity of the refined silicon 27. In the worst case, the particle 124 can be incorporated into the deposited silicon 27 itself. A further disadvantage of using hyper-eutectic alloy material 16 is that the depleted alloy material 16 can oxidize easily due to its spongy, rather powdery structure and therefore can be difficult to collect for re-melt/re-use.

For example, in terms of the alloy material 16 embodied as Cu—Si alloy material 16, the structure of the eutectic or hypo-eutectic copper-silicon material 16 is distinguished from hyper-eutectic alloys in such a way that the eutectic or hypo-eutectic copper-silicon material 16 inhibits cracks 122 formation during the cooling of the casting process, which can inhibit the absorption of oxygen and/or moisture once the formed eutectic or hypo-eutectic copper-silicon material 16 is exposed to air or other environmental conditions in which oxidants and/or moisture have access to the eutectic or hypo-eutectic copper-silicon material 16. This crack 122 inhibition can enhance the shelf-time of cast material 16 and further on, can reduce the amount of oxygen or other impurities for the process 8, which might be trapped in any cracks 22 in the case of hyper-eutectic alloys and released during the chlorination process 9.

For eutectic or hypo-eutectic copper-silicon alloy material 16, the lack of embedded silicon crystallites 120 (as formed in the case of hyper-eutectic alloys material) has some major consequences for the use in the chlorination reactor process 9. If silicon is extracted from crystallites 120 in hyper-eutectic alloy material 16 during the process 9, large voids or cavities 122 (i.e. expanded cracks 122) can be formed and the process gas 13 can penetrate into the bulk of the alloy material 16. This can result in a swelling/expansion of the alloy material 16 which can lead to a partial/complete disintegration or powdering of the alloy material 16. This disintegration can lower the filter effect of the alloy material 16, further described below, for holding back undesired impurities and thus can make the purification process 8 less efficient of the chlorination-deposition process.

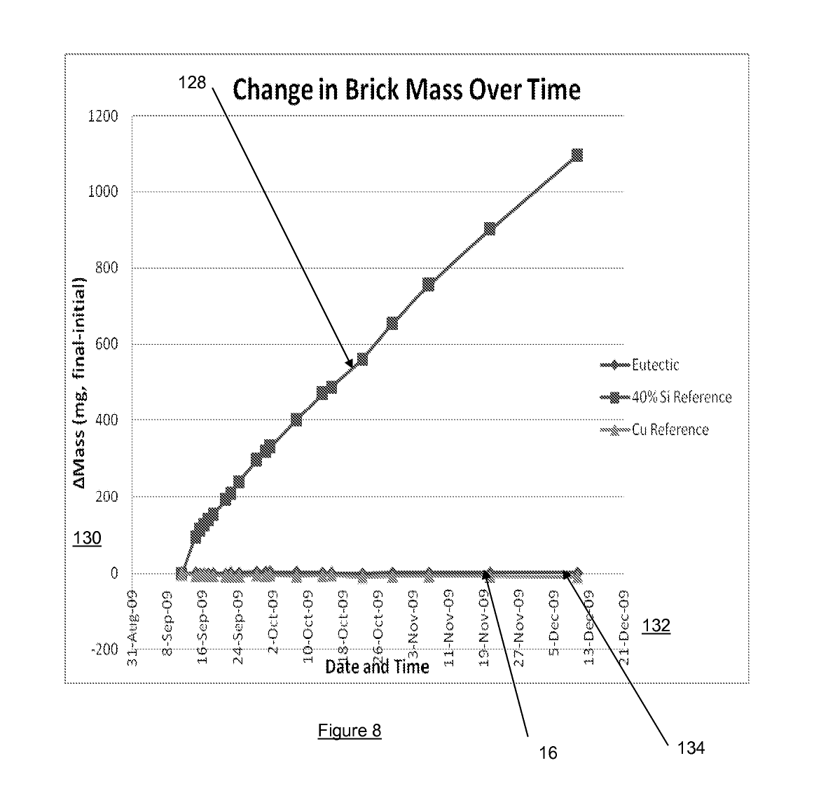

Referring to FIG. 8, oxidation behavior of eutectic copper-silicon alloy material 16 (approximately 16% wt silicon) versus oxidation behavior of hyper-eutectic alloy material 128 (40% wt silicon). Two pieces of similar shape (8×8×1.5 cm) alloy material 16,128 were stored under normal lab atmosphere and the material weight 130 was measured as a function of time 132. A piece of plain copper 134 was used as reference sample. The hyper-eutectic alloy 128 showed a continuous weight-gain, indicating ongoing oxidation. Within approximately 3 months, a weight gain of more than 1 g was measured, which was about 0.2% of the original total weight of the alloy material 128 (it was noted that after about 6 to 12 months, hyper-eutectic pieces 128 normally decomposed and fall apart). At the same time, the eutectic copper-silicon piece 16 did not show any significant weight gain, which may be explained by the solid, crack-free structure of the eutectic material 16.

### Forming of Alloy Material 16

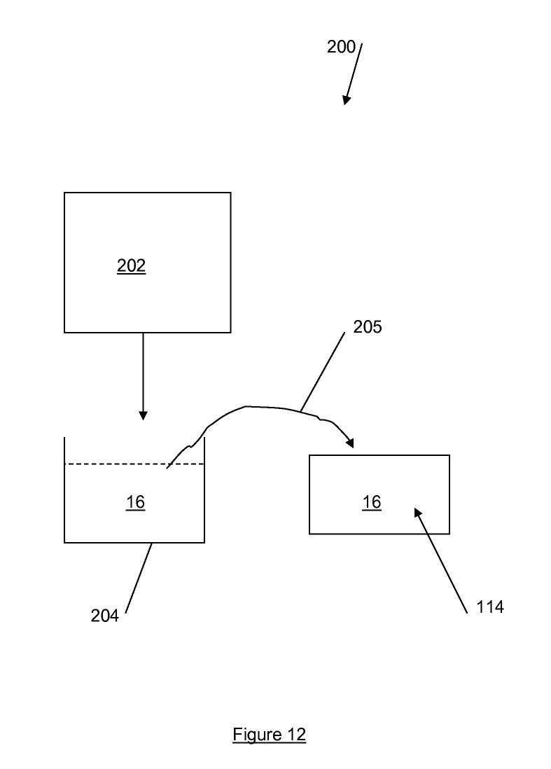

Referring to FIG. 12, shown is an example casting apparatus 200 used for a manufacturing process of the alloy material 16 by which a liquid material 202 containing measured percentage amounts of metal and silicon that are combined and then poured into a mold 204, which provides a hollow cavity of the desired physical shape of the alloy material 16. The molten liquid material 202 is then allowed to solidify at a controlled temperature to provide for the desired eutectic or hypo eutectic matrix 114 (see FIG. 7a,b/9a,b) of the alloy material 16. Further, the cooling process is controlled to maximize the integral matrix 114 properties of the alloy material 16 (e.g. which can be characterized as a multi crystalline structure) as well as to minimize any formation of crystallites 120 (see FIG. 7a). The solidified alloy material 16 is also known as a casting, which is ejected 205 or broken out of the mold 204 to complete the process.

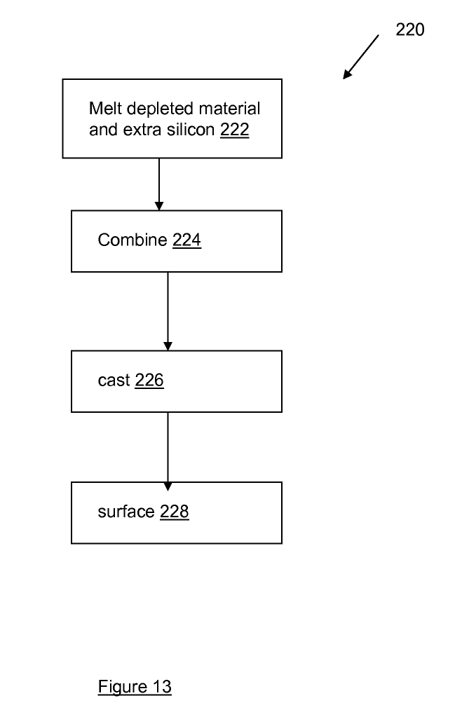

Referring also to FIG. 13, in accordance with the preferred embodiment, the eutectic or hypo-eutectic metal-silicon alloy material 16 is produced by a casting process 220, which can also be modified to be used as a recasting process for the silicon depleted alloy material 16. In this process, silicon, as for example m.g.-silicon, is melted 202 together with metal (e.g. copper) or with a hypo-eutectic silicon-copper mixture (e.g. depleted alloy material 16). The melting can be carried out in a graphite crucible or any crucible material, which withstands a silicon-copper melt 202 and does not unduly introduce additional impurities into the melt. Subsequently, the melt 202 is poured into the moulds 204, preferably, but not exclusively, graphite moulds 204, in order to form the desired eutectic or hypo-eutectic alloy material 16 of defined shape and geometry (e.g. by the shape of the mould 204). In contrast to metal-silicon alloys of higher silicon concentration, e.g. hyper eutectic composition, the eutectic or hypo-eutectic material 16 can be cast in a variety of different shapes (bricks, slabs, thin plates) since the material can be cooled stress-free. For example, the cooling process of the casting is configured to minimize/inhibit gas porosity, shrinkage defects, mould material defects, pouring metal defects, and/or metallurgical/matrix 114 defects. It is also recognised that the physical form/shape of the alloy material 16 can be configured for fixed bed or fluidized bed reactors (e.g. regions 12) of the apparatus 10.

Accordingly, the alloy material 16 can be cast to take any desired physical form, for example bricks, plates, granules, chunks, pebbles or any other shape, which allows an easy charging of the chemical vapour region 12 and which preferably provides a selected surface 136 to volume ratio above a defined ratio threshold.

Further, the cast eutectic or hypo-eutectic pieces 16 might be subject to a surface treatment before using it for the vapour gas production or they might be used directly. Possible surface treatments include e.g. sand-blasting or chemical etching, in order to remove any surface contamination or any oxide skin, as it might form during the casting process.

For example, the eutectic or hypo-eutectic bricks, slabs or plates (or whatever shape is required) can be used as source material 16 for the production of chlorosilanes in a chlorination reactor 12.

### Recasting of the Alloy Material 16

Referring to FIG. 13, shown is the recasting process 220 (for producing metal silicon alloy material 16 having a selected percent weight of silicon at or below the eutectic weight percent of silicon defined for the respective metal silicon alloy) performed after the anticipated amount of silicon is extracted from the eutectic or hypo-eutectic material 16 in the process 9 (see FIG. 3). The depleted slabs, bricks or plates or other physical form of the alloy material 16 can be removed from the chlorination region 12 since the alloy material 16 can retain its structural integrity due to the inhibition of cracking 122 due to the substantial absence (e.g. lack) of crystallites 120 present in the alloy material 16 for hypo eutectic and/or eutectic materials 16. Depending on the required purity level in the produced chlorosilane stream 13 or the deposited poly-silicon 27, respectively, the depleted material 16 may be re-melted and mixed with additional silicon in order to form fresh eutectic or hypo-eutectic material 16 for further use in the chlorination process 9. The number of recycles of the depleted material 16 can depend on threshold values for individual impurities and the impurity levels of the used mg.-silicon.

At step 222, melting the depleted metal silicon alloy material 16 is done such that the depleted metal silicon alloy material 16 has a concentration of silicon in the atomic matrix 114 increasing away from the exterior surface 136 of the metal silicon alloy material 16 towards the interior 140 of the metal silicon alloy material 16, such that the percent weight of the silicon adjacent to the exterior surface 136 in the depleted material is at or below the hypo eutectic weight percent of silicon range defined for the respective metal silicon alloy. At step 224, silicon is added (e.g. as metallurgical grade silicon) to the depleted metal silicon alloy material 16 (either melted, solid, or in partially melted form, for example) for enhancing the percent weight content of silicon of the resultant melt material to a selected percent weight of silicon at or below the eutectic weight percent of silicon defined for the respective metal silicon alloy. At step 226 the molten alloy material is cast to produce solid metal silicon alloy material 16 suitable for redeployment to the chemical vapour generation region of the apparatus 10 (see FIG. 1). An optional step 228 is surface treat the cast metal silicon alloy material 16.

It is recognised that surface treatment can be done with hypo-eutectic alloy (e.g. washing off metal-chlorides which have been accumulated on the surface. With hyper-eutectic, this may not possible due to the spongy structure, i.e. crack 122 formation, as discussed. Weather surface treatment can be done or not depending on the threshold value for the impurities contained in the alloy material 16 as a result of the casting process. Further, during casting, slagging-off of oxides and/or carbides could be done as a surface treatment of the alloy material 16.

### Filter Effect of Alloy Material 12

Referring to FIGS. 3,9a,9b, it is recognized in the case of hyper eutectic alloy material 16 (i.e. containing crystallites 120—see FIG. 7a), the swelling of the material 16 might influence or block the gas 13 flow and the release of powder and particles from the disintegration of the alloy material 16 (due to expansion/cracking) may introduce impurities/contaminates into the transport gas 15 that could contaminate the deposited silicon 27.

In the case of eutectic or hypo-eutectic copper-silicon (i.e. substantially absent the crystallites 120—see FIG. 7a), the alloy material 16 pieces do not swell or change their shape appreciably, thereby discouraging the formation/propagation of cracks 122 and resultant disintegration and/or destruction of the physical integrity of the alloy material 16. Accordingly, reaction with the input/process gas 13 takes place on the surface 136 of the hypo eutectic or eutectic material 16. Since silicon is known to have a significantly faster diffusion rate in copper-silicon than other metal elements, an efficient filter effect can be achieved for any impurities resident in the alloy material 16, as only those elements (i.e. Si or any other considered impurity elements in the alloy material 16), which have diffused to the surface 136 can react with the process gas 13.

Accordingly, the matrix 114 can be regarded as a filter or getter of impurities in the alloy material 16 (for example also in the matrix 114 with the copper and silicon), since the temperature and other operating parameters for the transport gas generation 9 provides for diffusion of the silicon in the matrix to be preferred (i.e. greater in magnitude) than diffusion of the considered impurity atoms (e.g. Cr, Fe, O2, N2, boron, phosphorous, etc.) through the alloy material 16. Therefore, the matrix 114 acts as a getter/filter during the chemical/metallurgical process of silicon reaction with the input gas 13 to absorb impurities that would otherwise get into the transport gas 15. It is also recognized that the diffusion/transfer rate of the silicon in the alloy matrix 114 is dependent upon a number of parameters including process 9 temperature and/or concentration gradient of Si in the matrix 114 (e.g. the concentration of Si in the matrix 114 will first deplete near the surface of the alloy material 16 upon reaction with the input gas 13, thus setting up a concentration gradient for silicon in the matrix 114 between the external surface and interior of the alloy material 16).

Atomic diffusion is a diffusion process whereby the random thermally-activated movement of atoms in a solid material 16 results in the net transport of atoms. The rate of transport is governed by the diffusivity and the concentration gradient 138. In the crystal solid state of the matrix 114, diffusion of the Si within the crystal lattice 114 occurs by either interstitial and/or substitutional mechanisms and is referred to as lattice diffusion. In interstitial lattice diffusion, a diffusant (such as Si in an Metal-Si alloy), will diffuse in between the lattice structure of another crystalline element. In substitutional lattice diffusion (self-diffusion for example), the Si atom can move by substituting place with another atom in the matrix 114. Substitutional lattice diffusion is often contingent upon the availability of point vacancies throughout the crystal lattice 114. Diffusing Si atoms migrate from point vacancy to point vacancy in the matrix 114 by the rapid, essentially random jumping about (jump diffusion).

Since the prevalence of point vacancies increases in accordance with the Arrhenius equation, the rate of crystal solid state diffusion can increase with temperature. For a single atom in a defect-free crystal matrix 114, the movement of the Si atom can be described by the “random walk” model. In 3-dimensions it can be shown that after n jumps of length α the atom will have moved, on average, a predefined distance. Atomic diffusion of Si in polycrystalline matrix 114 materials 16 can involve short circuit diffusion mechanisms. For example, along the grain boundaries and certain crystalline 114 defects such as dislocations there is more open space, thereby allowing for a lower activation energy for diffusion of the Si element. Atomic diffusion in polycrystalline 114 materials 16 is therefore often modeled using an effective diffusion coefficient, which is a combination of lattice, and grain boundary diffusion coefficients. In general, surface diffusion occurs much faster than grain boundary diffusion, and grain boundary diffusion occurs much faster than lattice diffusion.

Therefore, since silicon is known to have a significantly faster diffusion rate in metal-silicon than other impurity elements (those elements not desired for introduction/inclusion in the transport gas 15), the slower moving impurity elements are trapped in the bulk material 16, as the silicon in the matrix 14 is preferentially diffused to the surface 136 for reaction. In contrast to alloy with excess of silicon (i.e. crystallites 120), only Kirkendall-voids are predominantly formed in the matrix 114 upon depletion of the silicon element from the matrix 114, rather than larger cavities (e.g. cracks 122). The reaction of surface silicon with the process gas 13 creates a concentration gradient 138 and thus drives the silicon diffusion in direction to the surface 136. Since the amount of available silicon on the surface 136 is defined by the velocity of the solid-state diffusion, the temperature T during the chlorination process 9 is chosen appropriately, such that if the process 9 temperature is too low, the replenishment on the surface 136 with fresh silicon is too low. If the temperature is too high, impurities might migrate through the matrix 114 along with the silicon in sufficient quantities to be undesirably included in the transport gas 15 at concentrations above a defined impurity threshold. In principle, the process 9 can be operated at any temperature between 200 C and the melting point of the alloy material 16 (e.g. approximately 800 C marking the melting point Tmp of the eutectic alloy material 16 for Cu—Si alloy). For example, 200 C can be an example of a lower temperature boundary where diffusion of the silicon becomes below a defined minimum diffusion threshold.

In the case of desired metal silicon alloy materials 16 (e.g. Cu—Si), the approximately eutectic or hypo-eutectic alloy material 16 is heated by the heating means 6 to between a selected temperature range (e.g. 250 C-550 C, 300 C-500 C, 350 C-450 C, 375 C-425 C, 250 C-350 C, 350 C-550 C, 250 C-300 C, 400 C-500 C, 400 C-550 C) for the formation of trichlorosilane or other gas 13 and heated to higher temperatures (e.g. 450 C-Tmp, 500 C-Tmp, 550 C-tmp, 600 C-Tmp, 650 C-Tmp, 700 C-Tmp, 750 C-Tmp, 800 C-Tmp) if silicon tetrachloride or other gas 13 is preferred. Pressures of the process 9 can be in the range of 1-6 bars, for example. Further, it is recognized that the temperature and pressure process parameters could be adjusted in other metal silicon alloy material 16 (other than Cu—Si) configurations to facilitate/maximize the diffusion of the silicon through the matrix 114.

### Properties of Deposited Silicon 27

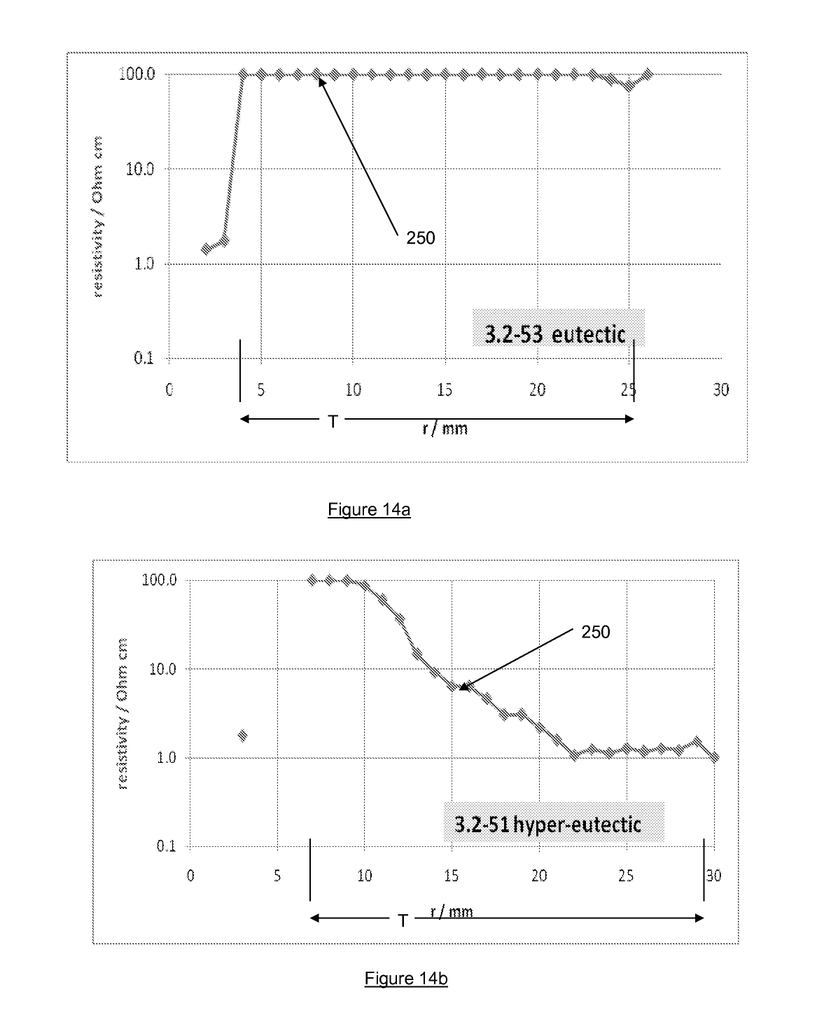

Referring to FIG. 14a,b: resistivity of purified silicon 27 using eutectic copper-silicon as source material (14a) and using hyper-eutectic alloy (silicon concentration 30%, 14b). The silicon 27 was deposited on hot filaments 26 by decomposing chlorosilane (i.e. trichlorosilane) produced in the chlorination region 12 by using the hyper-eutectic or the eutectic copper-silicon alloy material 16, respectively. After deposition, the poly-silicon rods 27 were cut into slices and the radial resistivity profile 250 was measured by a 4 point probe. (N.b. resistivity values larger 50/100 Ohm cm are set to 50/100 Ohm cm, since this marks roughly the range up to where bulk resistivity still can be measured; above 50/100 Ohm cm, influence of surface condition and grain boundaries becomes significant.) The eutectic copper-silicon shows a significantly better filter effect/getter effect than the hyper-eutectic one, as the resistivity value 250 remains substantially constant throughout the deposited silicon 27 thickness T. On the average, the material deposited from eutectic material shows a resistivity about one order of magnitude higher in selected thickness T locations of the material slice as compared to the resistivity of the silicon 27 deposited from hyper-eutectic material. (Note: the first 3-4 mm of the radius are not deposited silicon but the initial filament.). Accordingly, it is recognized that the resistivity of the deposited silicon 27 is maintained above a selected minimum resistivity threshold throughout a thickness of the deposited silicon 27 due at least in part to the filtering affect of the matrix 114 during the process 9.

### Example Operation of the Apparatus 10

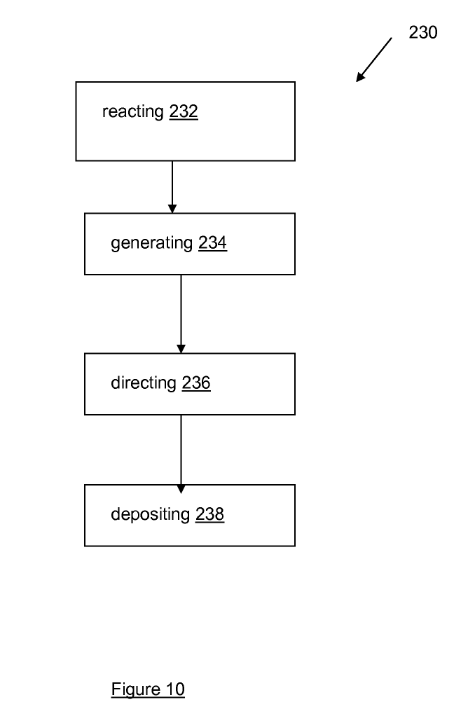

Referring to FIGS. 3, 10, shown is an example method 230 for using the apparatus 10 (see FIG. 3) for purifying silicon comprising the steps of: reacting 232 an input gas 13 with a metal silicon alloy material 16 having a silicon percent weight at or below the eutectic weight percent of silicon defined for the respective metal silicon alloy; generating 234 a chemical vapour transport gas 15 including silicon obtained from the atomic matrix 114 of the metal silicon alloy material 16; directing 236 the vapour transport gas 15 to a filament 16 configured to facilitate silicon deposition; and depositing of the silicon 27 from the chemical vapour transport gas 15 onto the filament 26 in purified form.

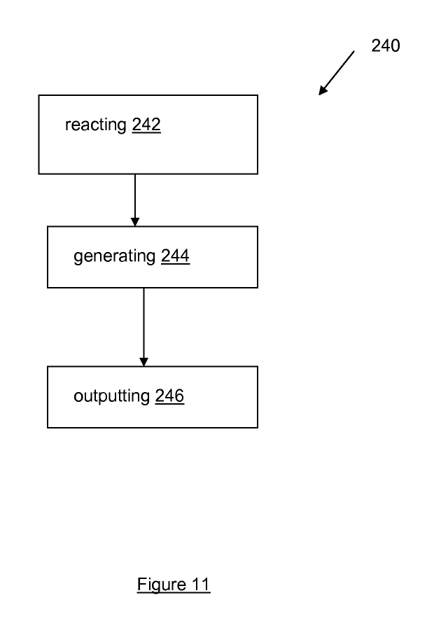

Referring to FIGS. 3, 11, shown is an example method 240 for producing chemical vapour transport gas 15 for use in silicon purification through silicon deposition 11 comprising the steps of: reacting 242 an input gas 13 with a metal silicon alloy material 16 having a silicon percent weight at or below the eutectic weight percent of silicon defined for the respective metal silicon alloy; generating 244 the chemical vapour transport gas 15 including silicon obtained from the atomic matrix 114 of the metal silicon alloy material 16; and outputting 246 the vapour transport gas 15 for use in subsequent silicon deposition 11.

Example Result of Alloy Material 16 Before and after Processing 8

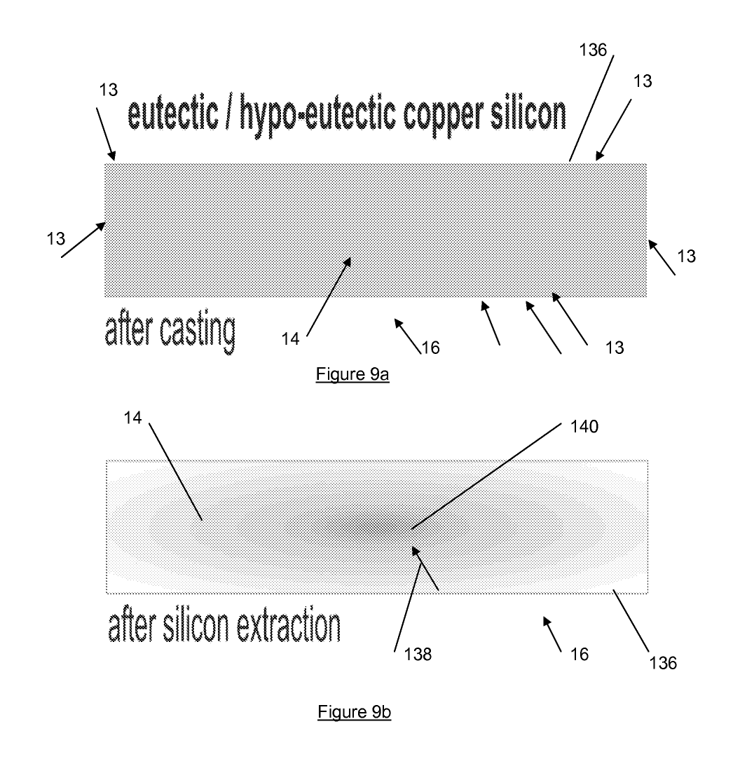

Referring to FIGS. 9a,b, shown is a schematic microstructure of a eutectic copper-silicon piece 16 before and after being subjected to the vapour generation process 9 (see FIG. 1). In FIG. 9a, after casting, the eutectic copper-silicon alloy material 16 is of uniform composition (e.g. single phase with a homogeneous distribution of the silicon in the copper matrix 14). In FIG. 9b, after extraction of silicon in the chlorination region 12: the eutectic (or similar in case of hypo-eutectic composition) is still intact and the alloy material 16 does not change appreciable its original shape that was inserted into the region 12. During extraction of silicon from the alloy material 16, in FIG. 9a, silicon diffuses to the surface 136 of the alloy material 16 through the matrix 14, where it reacts with the input gas 13. Once substantially depleted of silicon with respect to the requirements of the vapour generation process 9, the alloy material 16 contains a gradient 138 of silicon remaining resident in the matrix 14, such that the concentration of silicon in the matrix increases away from the exterior surface of the alloy material 16 towards the interior 140 (e.g. central region) of the alloy material 14.

It is recognized that the presence of any silicon crystallites 120 (see FIG. 7a) in the interior 140 of alloy material 16 would have to diffuse through the alloy material 16 to reach the surface 136 for subsequent interaction with the input gas 13. Accordingly, it is recognized that the rate of diffusion (e.g. matrix diffusion) of Si originally resident in the matrix 14 to the surface 136 and subsequent interaction with the input gases 13 would be different than the rate of diffusion (e.g. material diffusion) of Si not originally resident in the matrix 14 (e.g. in the crystallites 120—see FIG. 7a) to the surface 136 and subsequent interaction with the input gases 13. In certain cases, it is recognized that desired interaction between the Si in the crystallites 120 may preferentially occur via disintegration of the alloy material 16 via the above-described expansion/cracking and therefore not necessarily via diffusion through the alloy material 16 (i.e. cracking would expose the embedded crystallites 120 to the input gas 13.

### EXAMPLES

The following examples illustrate the properties and the behavior of the eutectic and hypo-eutectic copper-silicon alloy materials 16 for the use in chlorosilane gas 13 production 9 and subsequent production 11 of high purity silicon 27. These are examples only and are not meant to be limiting in any way, in particular to the different metals that can be used in the metal silicon alloy materials 16 in keeping with the spirit of the described metal silicon hypo eutectic and eutectic alloy materials 16 having a defined absence of excess silicon outside of the metal silicon matrix 114 (e.g. as precipitated crystallites 120).

### Example 1

A slab of eutectic copper-silicon (8×8×1.5 cm) was cast, the weight was measured and it was exposed to atmosphere (normal lab atmosphere). For comparison, a hyper-eutectic slab with a silicon concentration of 40% wt silicon and similar dimensions was cast and handled the same way as the eutectic one. For reference, a pure copper plate was used. The weight of the 3 different pieces was measured over a period of three months (see FIG. 8). Whereas the hyper-eutectic alloy slab showed a continuous increase of weight over time (after three months, the weight had increased by more than 1 gram, the initial weight of the piece was approx. 400 g), no significant change was detected for the eutectic copper-silicon. This indicates that the hyper-eutectic alloy absorbs oxygen and/or moisture in continuous manner, the amount of gained weight implies that a continuous oxidation goes on. Micrographs of cast hyper-eutectic alloy slabs show an intense net-work of micro-cracks, which provides a large surface for oxidation. Further, it can be assumed that the oxidation results in a volume change/expansion, which creates more cracks and thus facilitates further oxidation. Since the eutectic (as well as hypo-eutectic) material does not preferentially form micro-cracks during casting, oxidation can occur only on the slab 16 surface itself but does not penetrate into the bulk of the material 16.

### Example 2

Two slabs of eutectic and of hyper-eutectic (30% wt silicon) composition where exposed to normal atmosphere, no special treatment was applied. After a shelf-time of approximately 6 months, the hyper-eutectic slab lost its integrity and fell apart, the eutectic slab did not change and kept its solid structure appreciably.

### Example 3

Eutectic plates of 3 mm thickness and a length of 20×10 cm were cast in graphite moulds. The plates could be produced crack-free. For comparison, casting of hyper-eutectic plates (30% wt and 40% wt silicon) of similar geometry always resulted in sever cracking and breaking, caused at least in part by the stress due to the different thermal expansion coefficients of the eutectic matrix 114 and the interspersed silicon crystallites 120.

### Example 4

Eutectic slabs (bricks) of 8×8×1.5 cm size have been placed in a chlorination reactor (see application “Method and Apparatus for the Production of Chlorosilanes”). Total amount of eutectic-copper slabs was 40 kg, the temperature in the chlorination reactor during the reaction with the process gas was in the range of 300 to 400 C. The produced chlorosilanes were sent into a deposition reactor without further purification (see application “Method and Apparatus for Silicon Refinement”). Over a period of 90 hours, 4 kg of silicon had been extracted from the eutectic slabs and deposited on heated silicon filaments, placed in a separate deposition chamber. The average deposition rate was 44 g/h. After deposition, the radial resistivity profile of the deposited poly-silicon rods was measured using 4 point probe. Over the whole radius, the resistivity was in the range of 100 Ohm cm or higher, indicating a very efficient impurity gettering by the eutectic copper-silicon (see FIG. 12a). Over the whole chlorination process, the eutectic copper-silicon slabs did not appreciably change their physical shape and after the process, they were fully intact, such that they maintained their physical structural integrity.

For comparison, hyper-eutectic alloy of 40 wt % silicon was cast in a similar way and used in the same chlorination process 9 under similar conditions with respect to temperature and gas composition. The weight of the used hyper-eutectic alloy was 26 kg. The produced chlorosilanes were sent into a deposition process 11 without further purification. A total of 5.4 kg of silicon was deposited, the average deposition rate was 46 g/h. The corresponding resistivity profile over the radius of the deposited poly-silicon shows a significantly lower resistivity, especially towards the edge of the slice (FIG. 12b). This clearly indicates that the getter effect for electrically active impurities (i.e. boron, as confirmed by chemical analysis) is less for hyper-eutectic alloy compared to eutectic and/or hypo eutectic one. During the chlorination process, the hyper-eutectic slabs did swell and a large part of them did fell apart, forming an extensive amount of powder.

### Example 5

Hypo-eutectic slabs (eta-phase—12% wt silicon) had been cast and placed in a chlorination reactor. Temperature during chlorination was in the range of 270 to 450 C. 54 kg of hypo-eutectic copper-silicon was used. The produced chlorosilanes were sent into a deposition reactor without further purification. Within 117 hours, 4 kg of poly-silicon was deposited on heated filaments. The hypo-eutectic slabs did not change its shape, after extraction of silicon, slab integrity was fully given. No substantive powdering or swelling was detected.

While this invention has been described with reference to illustrative embodiments and examples, the description is not intended to be construed in a limiting sense. Thus various modifications of the illustrative embodiments, as well as other embodiments of the invention, it will be apparent to persons skilled in the art upon reference to this description. This includes especially any copper-silicon compositions which are not exactly the ones described in the embodiment or in the examples, but are closed to the eutectic or the hypo-eutectic composition, or any composition in between.

While this invention has been described with reference to illustrative embodiments and examples, the description is not intended to be construed in a limiting sense. Thus, various modification of the illustrative embodiments, as well as other embodiments of the invention, will be apparent to persons skilled in the art upon reference to this description. It is therefore contemplated that the appended claims will cover any such modifications or embodiments. Further, all of the claims are hereby incorporated by reference into the description of the preferred embodiments.

All publications, patents and patent applications referred to herein are incorporated by reference in their entirety to the same extent as if each individual publication, patent or patent application was specifically and individually indicated to be incorporated by reference in its entirety.

1. A method for purifying silicon comprising:
reacting an input gas with a metal silicon alloy material having a silicon percent weight at or below the eutectic weight percent of silicon defined for the respective metal silicon alloy;
generating a chemical vapour transport gas including silicon obtained from the atomic matrix of the metal silicon alloy material;
directing the vapour transport gas to a filament configured to facilitate silicon deposition; and
depositing the silicon from the chemical vapour transport gas onto the filament in purified form.

2. The method of claim 1, wherein the weight percent of silicon is a weight percent range.

3. The method of claim 2, wherein the weight percent range is approximately 8 to approximately 16 percent weight silicon for the metal silicon alloy using copper as the metal.

4. The method of claim 1, wherein the vapour transport gas includes chlorosilanes and the metal silicon alloy uses copper as the metal.

5. The method of claim 4, wherein the input gas comprises hydrogen chloride, hydrogen or a combination of hydrogen chloride and hydrogen.

6. The method of claim 5, wherein the copper silicon alloy is a metallurgical grade silicon.

7. The method of claim 2, wherein the metal of the metal silicon alloy is selected from the group consisting of: copper; nickel; iron; silver; platinum; palladium; and chromium.

8. The method of claim 3, wherein the copper silicon alloy comprises from about 1 to about 16 percent weight of silicon.

9. The method of claim 8, wherein the silicon-copper alloy comprises from about 10 to about 16 weight of silicon.

10. The method of claim 4, wherein the copper silicon alloy material is at a controlled alloy material temperature.

11. The method of claim 10, wherein the controlled alloy material temperature is between a minimum diffusion threshold temperature and a melting point temperature of the copper silicon alloy material.

12. The method of claim 10, wherein the controlled alloy material temperature is between a temperature of about 300° C. to about 500° C.

13. The method of claim 1 further comprising producing a silicon concentration gradient between the exterior surface of the metal silicon alloy material and the interior of the metal silicon alloy material for facilitating atomic diffusion of the silicon through the metal silicon matrix to the exterior surface for consumption by the input gas.

14. The method of claim 13, wherein the presence of silicon crystallites in the metal silicon alloy material is below a defined crystallite threshold.

15. The method of claim 14, wherein the defined crystallite threshold is a property of a hypo eutectic percent weight of silicon in the metal alloy.

16. The method of claim 14, wherein the defined crystallite threshold is a property of an eutectic percent weight of silicon in the metal alloy.

17. The method of claim 1 further comprising the metal silicon alloy material acting as a getter for defined impurity components present in the metal silicon alloy material.

18. The method of claim 17, wherein the filtering of the defined impurity components facilitates the production of the purified silicon having a resistivity that remains above a defined minimum resistivity threshold throughout the deposited silicon thickness.

19. The method of claim 18, wherein a resistivity is at or greater than one order of magnitude higher in selected thickness locations of the material slice for the deposited silicon as compared to the resistivity deposited silicon from hyper eutectic alloy material.

20. The method of claim 1, wherein the metal silicon alloy material has an affinity for oxidation below a defined affinity threshold to facilitate the material retaining its structural integrity due to exposure of the material to oxidants.

21. The method of claim 14, wherein the presence of silicon crystallites in the metal silicon alloy material below a defined crystallite threshold inhibits decreases in the structural integrity of metal silicon alloy material during exposure to the input gas.

22. An apparatus for purifying silicon comprising:
a first reactor for reacting an input gas with a metal silicon alloy material having a silicon percent weight at or below the eutectic weight percent of silicon defined for the respective metal silicon alloy and for generating a chemical vapour transport gas including silicon obtained from the atomic matrix of the metal silicon alloy material;
an output for directing the vapour transport gas to a filament configured to facilitate silicon deposition; and
a second reactor for depositing the silicon from the chemical vapour transport gas onto the filament in purified form.

25. A metal silicon alloy material having a silicon percent weight at a selected eutectic weight percent of silicon defined for the respective metal silicon alloy for use in a chemical vapour deposition (CVP) process, such that the presence of silicon crystallites in the alloy material is at or below a defined maximum crystallite threshold.

27. A metal silicon alloy material having a silicon percent weight at or below the eutectic weight percent of silicon defined for the respective metal silicon alloy for use in a chemical vapour deposition (CVP) process.
